(19) United States
(12) Patent Application Publication
(10) Pub. No.: US 2011/0056532 A1
(43) Pub. Date: Mar. 10, 2011

(54) Method for manufacturing thin crystalline solar cells pre-assembled on a panel

(75) Inventors: Tirunelveli S. Ravi, San Jose, CA (US); Ananda Kumar, Fremont, CA (US); Kramadhati V. Ravi, Atherton, CA (US)

(73) Assignee: CRYSTAL SOLAR, INC., Santa Clara, CA (US)

(21) Appl. No.: 12/556,357

(22) Filed: Sep. 9, 2009

(51) Int. Cl. H01L 31/042; H01L 31/18

(52) U.S. Cl. 136/244; 438/72; 257/E31.119

(57) ABSTRACT

A method for fabricating a photovoltaic (PV) cell panel wherein each of a plurality of silicon donor wafers has a separation layer formed on its upper surface, e.g., porous anodically etched silicon. On each donor wafer, a PV cell is then partially completed including at least part of inter-cell interconnect, after which plural donor wafers are laminated to a backside substrate or frontside. All of the donor wafers are then separated from the partially completed PV cells in an exfoliation process, followed by simultaneous completion of the remaining PV cell structures on PV cells. Finally, a second lamination to a frontside glass or a backside panel completes the PV cell panel. The separated donor wafers may be reused in forming other PV cells. Use of epitaxial deposition to form the layers of the PV cells enables improved dopant distributions and sharper junction profiles for improved PV cell efficiency.

### BACKGROUND OF THE INVENTION

1. Field of the Invention

This invention relates generally to methods and systems for fabricating photovoltaic (PV) solar cells. More particularly, it relates to fabricating arrays of solar cells by partially fabricating PV cell structures on donor wafers having a separation layer, laminating multiple donor wafers to a substrate and exfoliating the thin PV cell structures from the donor wafers, and then simultaneously completing the PV cell structures.

2. Description of the Related Art

Silicon is the basic ingredient of many solar cell technologies ranging from thin-film amorphous silicon solar cells to single-crystal silicon wafer-based solar cells. High efficiency solar cells start with electronic or solar grade polysilicon grown by chemical vapor deposition. The polysilicon is melted and ingots are pulled from the melt in the Czochralski process. The silicon ingot is then sliced into thin wafers by sawing, and solar cells are formed on the wafers by traditional semiconductor techniques and interconnected and packaged to last at least 25 years. Such silicon wafers are relatively expensive and thus severely impact the costs of solar cells in formed and packaged in the standard wafers.

Throughout the past quarter century, significant innovations in all aspects of solar cell manufacture has allowed significant reduction in cost. For example, from 1990 to 2006, wafers have decreased in thickness from 400 μm to 200 μm. However, the cost of crystalline silicon still constitutes a significant part of the overall cost, as measured by many of the metrics used to characterize the cost of crystalline solar technology.

A flow chart of a conventional process for manufacturing solar panels is illustrated in FIG. 1. Stock blank monocrystalline wafers cut from an ingot are supplied in block 102. Saws shape ingots into a quasi-square cross section having rounded corners, and the squared ingot is cut or wafered into individual wafers. The silicon wafers are used in step 104 as substrates for fabricating the structure of the photovoltaic (PV) cell structure, which is fundamentally a vertically oriented photodiode on the top surface of the wafers. The fabrication process uses epitaxial or diffusion furnace methods to form the required thin silicon layers doped n-type and p-type. After the PV cells have been fabricated, the wafer tiles are then assembled in step 108 onto a panel substrate in an X-Y array, and contacts to the n-type and p-type layers are added, often by screen printing or sputter deposition of metals onto the PV wafers followed by soldering tinned copper ribbons to bus bars of the deposited metal.

Further reductions in silicon thickness, and thereby the cost of monocrystalline silicon solar cells, is expected to be best offered by techniques in which a monocrystalline silicon substrate, often referred to as a “donor wafer” or sometimes “donor wafer” or “substrate wafer”, is first treated to form a separation layer. Then a thin epitaxial silicon layer is deposited on the treated surface, and finally the deposited epitaxial layer is separated from the donor wafer to be used as thin (2-100 μm) single crystal silicon solar cells. The donor wafer is thereafter sequentially re-used to form several additional such epitaxial layers, each producing its own solar cell. There are several known standard techniques for growing the separation layer, such as forming a composite porous silicon layer by anodically etching a discontinuous oxide masking layer, or by high energy implantation of oxygen or hydrogen to form the separation layer within the donor wafer.

The epitaxial silicon layer that is formed needs to be separated intact from the donor wafer with little damage in order to thereafter fabricate the eventual solar cell module. We believe that this separation process is preferably done by ‘peeling’ in the case where the separation layer is highly porous silicon. Peeling implies parting of an interface starting from one edge and continuing until complete separation occurs.

It has been difficult or impossible to handle very thin solar cells using the prior art process in which individual PC cells are formed prior to assembly into the final X-Y array needed for a completed solar panel.

One basic process in the prior art for manufacturing epitaxial single crystal silicon solar modules includes the following steps: (1) forming a separation layer on a relatively thick, single crystal silicon substrate; (2) growing a single crystal epitaxial layer and fabricating the solar cells on the epitaxial layer and the basic cell interconnections on the solar cells; (3) separating the epitaxial layer at the cell level; and (4) assembling and packaging several such cells to form a solar panel. Despite the great potential of this prior art method for producing relatively inexpensive, highly efficient solar cells, the method has eluded commercial success for at least three main reasons: (1) some of the unit processes are deficient and difficult to reproduce; (2) manufacturing strategy generally starts and ends with making individual wafer-size solar cells and, thereafter, assembling them into solar panels; and (3) thin cells separated from their donor wafers and prior to bonding to foreign substrates easily break and often warp because of layers of different materials deposited on them. The last two problems arise in part from handling the thin epitaxial photovoltaic layer between its separation from the donor wafer and its assembly on the panel along with other such epitaxial photovoltaic layers. As a result, economical processing awaits the development of new tools and equipment.

### SUMMARY OF THE INVENTION

A general aspect of the invention involves forming a photovoltaic junction as a solar cell in an epitaxial layer grown on a donor wafer or by diffusion of the appropriate dopant (boron or phosphous) into the epitaxial layer, depositing anti-reflection layers on the junctions, making metal contacts in the form of a grid, and attaching plural such donor wafers to a mounting substrate with the epitaxial layer adjacent the mounting substrate, and separating the donor wafers from the epitaxial layers still attached to the mounting substrate. In different embodiments, the mounting substrate may be a transparent glass adhered to the front side of solar cells or adhered to the back side of the solar cells so that a non-transparent mounting substrate may be used.

Some inter-cell interconnections may be included in the adhesive laminating the epitaxial layers of the solar cells with the mounting substrate.

One aspect of the invention includes forming interdigitated backside contact photovoltaic (PV) cells on a multiplicity of donor wafers, followed by tabbing and stringing of the PV cell contacts and lamination of the multiplicity of donor wafers to a substrate using a first adhesion layer. The backsides of the donor wafers are then clamped to a chuck assembly and exfoliated from the thin PV cell structures, followed by lamination of the PV cells to a frontside glass layer using a second adhesion layer.

Another aspect of the invention includes forming the frontside structures of PV cells on a multiplicity of donor wafers, then tabbing the frontside contacts, followed by lamination of the multiplicity of donor wafers to a frontside glass using a first adhesion layer. The backsides of the donor wafers are then clamped to a chuck assembly and exfoliated from the thin PV cell structures, followed by completion of the backsides of the PV cells. The PV cells are then strung together, followed by lamination of the donor wafers to a frontside glass layer using a second adhesion layer. For this aspect of the invention, conventional series electrical connections between the PV cells in each string are employed, with the strings being connected in parallel in the completed solar panel.

Yet another aspect of the invention includes forming the frontside structures of PV cells on a multiplicity of donor wafers, then tabbing and stringing the frontside contacts, followed by lamination of the multiplicity of donor wafers to a frontside glass using a first adhesion layer. The backsides of the donor wafers are then clamped to a chuck assembly and exfoliated from the thin PV cell structures, followed by completion of the backsides of the PV cells. The PV cells are then tabbed and strung together, followed by lamination of the donor wafers to a frontside glass layer using a second adhesion layer. For this aspect of the invention, unconventional parallel electrical connections between the PV cells in each string are employed, with the strings being connected serially in the completed solar panel.

A further aspect of the invention includes forming a separation layer in the multiple wafers by anodically etching preferably monocrystalline wafers to form a porous silicon layer. Although the anodic etching may be done on an assembled array of solar cell tiles, it may also be done on individual wafers.

A yet further aspect of the invention includes placing metallic ribbons to be used as inter-cell interconnects in an adhesive layer applied to the mounting substrate and then placing the donor wafers and associated PV cells on the adhesive layer with one or more contacts formed in the PV cells aligned with the ribbons. When the adhesive is cured during a thermal laminating process to join the PV cells as attached donor wafers to the mounting substrates, the ribbons provide a sturdy electrical contact. Both ends of the ribbons may be attached to adjacent PV cells on the same side or one end may be bent to contact the adjacent PV cell on the other side.

Silicon layers may be deposited, preferably epitaxially, by chemical vapor deposition on the porous silicon layer or onto crystalline silicon disposed over the separation layer. Dopant precursors may be included in the deposition to produce a layered semiconductor structure including p-n junctions or may be diffused into existing silicon layers.

Contacts may be fully or partially added to the silicon structures attached to the substrate or glass layer by an adhesion layer. Additional layers may be applied to facilitate further processing. The adhesion layer preferably is a polymer that flows but when cured hardens to a transparent solid, for example ethylene vinyl acetate (EVA). More preferably the polymer is applied in sheet form at room temperature but flows at intermediate temperatures below the hardening temperature.

The fully or partially processed solar cells may be delaminated and separated from the donor wafers across the separation layer, such as porous layers, by a progressive peeling action.

### BRIEF DESCRIPTION OF THE DRAWINGS

FIG. 1 is a flow chart of a conventional prior art solar panel manufacturing process.

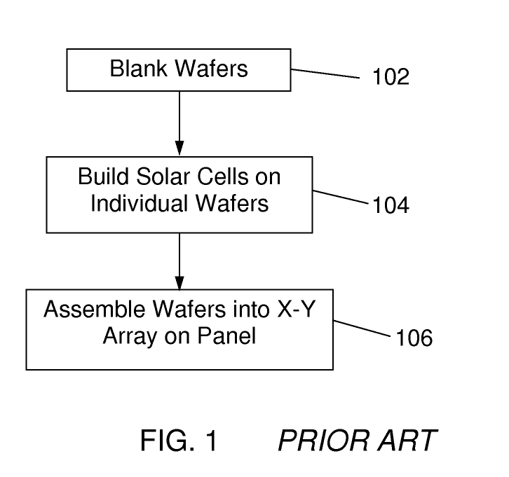

FIG. 2 is a flow chart of a first embodiment of a solar panel manufacturing process of the present invention utilizing PV cells with interdigitated backside connections (IBC).

FIG. 3 is a schematic isometric view of an anodic etcher capable of simultaneously etching multiplicities of wafers attached in a vertical orientation to each of a plurality of support frames.

FIG. 4 is a schematic side cross-sectional view of a donor wafer with interdigitated backside contact PV cell structures formed on the upper surface of the donor wafer.

FIG. 5 is a plan view of interdigitated contacts in the first embodiment.

FIG. 6 is a schematic side cross-sectional view taken along section line A-A of FIG. 5 of a donor wafer tabbed and attached to a backside substrate using an adhesive layer, for example, of ethyl vinyl acetate (EVA).

FIG. 7 is a schematic side cross-sectional view of two of the donor wafers of FIG. 5 taken along a perpendicular section line from that of FIG. 6 with the donor wafers tabbed, strung together, and attached to a backside substrate using an adhesive layer such as of ethyl vinyl acetate (EVA).

FIG. 8 is a plan view of the ribbons interconnecting multiple solar cells of FIGS. 6 and 7.

FIG. 9 is an electrical schematic diagram of a solar cell array according to the first and second embodiments of the present invention.

FIG. 10 is a schematic side cross-sectional view of the solar cell array from FIG. 8 clamped to a segmented chuck prior to separation across the highly porous silicon films.

FIG. 11 is a schematic side cross-sectional view of the solar cell array from FIG. 10 after the beginning of separation across the highly porous films.

FIG. 12 is a cross-sectional view of the solar cell array from FIG. 11 after completion of the separation across the highly porous films.

FIG. 13 is a schematic side cross-sectional view of the solar cell array from FIG. 12 after completing the remaining frontside fabrication steps, followed by tabbing and stringing, and attachment of a frontside glass layer using an EVA adhesion layer.

FIG. 14 is a flow chart of a second embodiment of a solar panel manufacturing process of the present invention utilizing PV cells with frontside/backside connections and conventional tabbing and stringing.

FIG. 15 is a schematic side cross-sectional view of a donor wafer with frontside PV cell structures formed on the upper surface of the donor wafer.

FIG. 16 is a plan view of the bottom contacts formed in the wafer of FIG. 15.

FIG. 17 is a schematic side cross-sectional view of the donor wafer from FIG. 15 tabbed on the PV cell frontsides and then attached to a frontside glass layer using an EVA adhesion layer.

FIG. 18 is a schematic side cross-sectional view of two of the donor wafers of FIG. 17 taken along a perpendicular section line.

FIG. 19 is a schematic side cross-sectional view of the solar cell array from FIGS. 17 and 18 after completion of the separation across the highly porous films and after deposition of a patterned passivation layer, followed by deposition of titanium and aluminum layers.

FIG. 20 is a schematic side cross-sectional view of the solar cell array of FIGS. 17 and 18 in an alternative process to that illustrated in FIG. 19 wherein a laser beam forms the contacts through the passivation layer.

FIG. 21 is a schematic side cross-sectional view of the solar cell array from either FIG. 19 or 20 after deposition of a conducting adhesive layer and stringing of the PV cells, followed by attachment of a backside substrate using an EVA adhesion layer.

FIG. 22 is a flow chart of a third embodiment of a solar panel manufacturing process of the present invention utilizing PV cells with frontside/backside connections and non-conventional tabbing and stringing.

FIG. 23 is a schematic side cross-sectional view in a third embodiment of two of the donor wafers from FIG. 15 tabbed and strung on the PV cell frontsides, and then attached to a frontside glass layer using an adhesion layer, for example, of EVA.

FIG. 24 is a schematic side cross-sectional view of the solar cell array from FIG. 23 after completion of the separation across the porous films and after formation of a patterned passivation layer, covered by of titanium and aluminum layers.

FIG. 25 is a schematic side cross-sectional view of the solar cell array from FIG. 24 after deposition of a conducting adhesive layer and tabbing and stringing of the PV cell backsides, followed by attachment of a backside substrate using another adhesion layer.

FIG. 26 is an electrical schematic diagram of a solar cell array according to the third embodiment of the present invention.

### DETAILED DESCRIPTION

Various aspects of the present invention encompass several methods for manufacturing photovoltaic (PV) solar cell arrays sharing the common feature that epitaxial layers are formed on top of separation layers formed in donor wafers and solar cells structures are partially formed in and on the epitaxial layer before multiple donor wafers have their epitaxial sides laminated to a solar support panel. The donor wafers are separated from the panel across the separation layers and the remainder of the solar cell processing and interconnection is performed on the solar cells bonded to the panels. The invention will be described for three embodiments of the fabrication process and resulting solar cell structure: (1) a first embodiment utilizing interdigitated backside contact (IBC) PV cells with a tabbing/stringing concept similar to the prior art, (2) a second embodiment utilizing frontside/backside contact PV cells with a tabbing/stringing concept similar to one found in the prior art, and (3) a third embodiment utilizing frontside/backside contact PV cells with an unconventional tabbing/stringing concept. However, the invention is not limited to the described embodiment.

Although the invention is not so limited, the detailed embodiments include a separation layer formed of a porous silicon layer which is formed at the surface of the monocrystalline silicon donor wafer and on which one or more epitaxial silicon layers may be deposited.

### First Embodiment

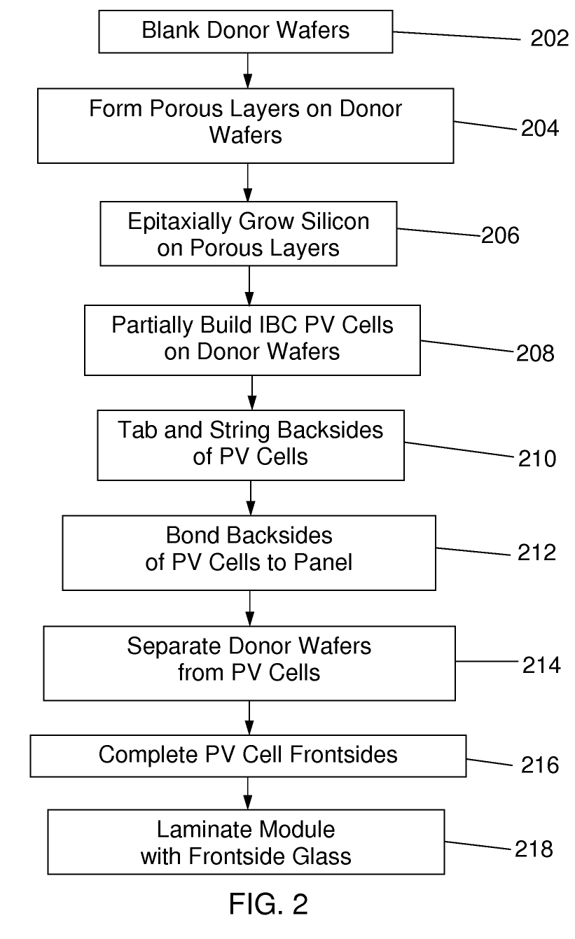

A flow chart shown in FIG. 2 of a first embodiment of a solar panel manufacturing process of the present invention utilizes PV cells with interdigitated backside connections (IBC). A multiplicity of blank monocrystalline silicon donor wafers in block 202, preferably with a square or quasi-square shape, are anodically etched in step 204 to form porous silicon separation layers on the upper surfaces of the respective donor wafers. In step 206, silicon is epitaxially grown on the porous silicon layers, for example, by chemical vapor deposition (CVD). A multiplicity of interdigitated backside contact (IBC) PV cells are at least partially formed in step 208, for example, using the processing steps described in application Ser. No. 12/290,582. Typically, one PV cell is formed on each donor wafer. The IBC PV cells from step 208 are then tabbed and strung together in step 210, followed in step 212 by attachment to a backside panel substrate using an adhesion layer, for example, of ethyl vinyl acetate (EVA). A typical size for a solar panel is 2 by 4 feet (60 by 120 cm). The backsides of the donor wafers in the PV cell array formed in step 212 are in step 214 next clamped and exfoliated from the multiple PV cells now bonded to the backside panel substrate. The PV cell front sides are now completed in step 216 on the multiple PV cells supported on the backside substrate using only low temperature processes compatible with the EVA adhesion layer used to attach the backside substrate in step 212. Finally, in step 218, a front side glass layer is attached to the PV cell array using a second adhesion layer.

The first step in the described processes for manufacturing solar panels in all the illustrated embodiments involves the formation of a porous silicon separation layer. The purpose of this layer is to enable the reuse of the silicon donor wafers or tiles to form multiple solar cells. This reuse is possible because the solar cells do not need the full thickness of the wafers; instead, the porous layer is developed in only a partial thickness of the donor wafers in a preferred range of 25-50 μm or even less. Since the thickness of the donor wafer is typically at least hundreds of microns (even for thin silicon wafers) and can be up to 10 mm or greater (for thick silicon blocks or laminated silicon wafers or blocks), it is possible to fabricate a substantial number of solar cell arrays from a single corresponding array of donor wafers. Advantageously, the solar cells are built on top of a porous silicon separation layer including steps of epitaxially depositing silicon layers forming the PV cell on top of the porous silicon. K. V. Ravi, in co-pending U.S. patent application Ser. Nos. 12/290,582 and 12/290,588, both filed Oct. 31, 2008, both incorporated herein by reference, describes the fabrication processes for backside contact PV cells, and frontside/backside contact PV cells, respectively. The described processes involve the formation of a porous surface layer in the silicon donor wafers, typically by anodic etching, and growth of an epitaxial silicon layer over the porous layer, and at least partial development of the solar cell in the epitaxial layer while still attached to the donor wafer.

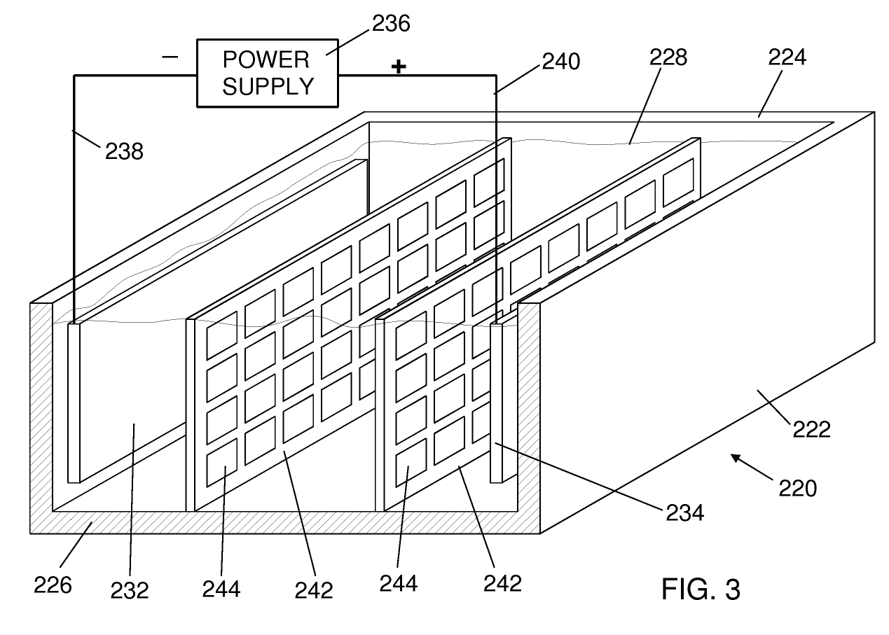

An anodic etcher 220 illustrated in the schematic sectioned isometric view of FIG. 3 is capable of simultaneously etching multiplicities of donor wafers as described in Ser. Nos. 12/290,582 and 12/290,588. T. S. Ravi et al. provide further details of the anodic etching process for formation of the porous separation layers in co-pending U.S. patent application Ser. No. 12/399,248, filed 6 Mar. 2009, incorporated by reference herein. The anodic etcher 220 is formed in a tank having opposed end walls 222, two opposed dielectric sidewalls 224 and a dielectric bottom wall 226 and filled with an electro-etching solution 228, which is typically hydrofluoric acid (HF). Two electrodes 232, 234 disposed in or near the end walls 222 are preferably formed of platinum and are electrically connected to a power supply 236 by respective wires 238, 240. One or more support frames 242 are mounted in the electro-etching solution 228 between the two electrodes 230, 232. The frames 242 extend above the surface of the electro-etching solution 228 and are sealed to the sidewalls 224 and the bottom wall 226 to form a serial circuit between the electrodes 232, 234. In the illustrated embodiment, each frame 242 mounts multiple donor wafers 244, but other embodiments mount only a single wafer on each frame 242. If the support frames 242 have openings in which donor wafers 244 are mounted, then both the front and back sides of the donor wafers 244 will be exposed to the electrolytic solution 228, but the donor wafers 244 should be sealed to the support frame 242 to electrically isolate the electrolytic solution 228 across each support frame 242.

In anodic etching in HF and similar non-oxidizing electrolytes, when a DC voltage is applied to the front sides of the donor wafers 244 which is more positive than that applied to the back sides, the front sides are anodically etched. The anodic etching of monocrystalline silicon creates pores within the silicon surrounded by remaining portions of the monocrystalline silicon. As a result, the porous silicon layer can serve as an epitaxial template to allow substantially monocrystalline silicon to be epitaxially grown on the porous silicon layer. However, the porous silicon layer is substantially weaker than the underlying monocrystalline donor wafers 244 or any after grown epitaxial silicon and thus can serve as a separation layer.

Etching a large array of the silicon donor wafers 244 to produce the needed porous layer structures requires uniform anodic current distribution across all individual donor wafers 244 attached to each support frame 242, which is obtained by the liquid electrolyte 228 contacting both the front and the back of each wafer 244.

However, porous silicon layers in the donor wafers can be obtained in other ways. Indeed, other types of separation layers may be used such as ion implanted layers well beneath the surface.

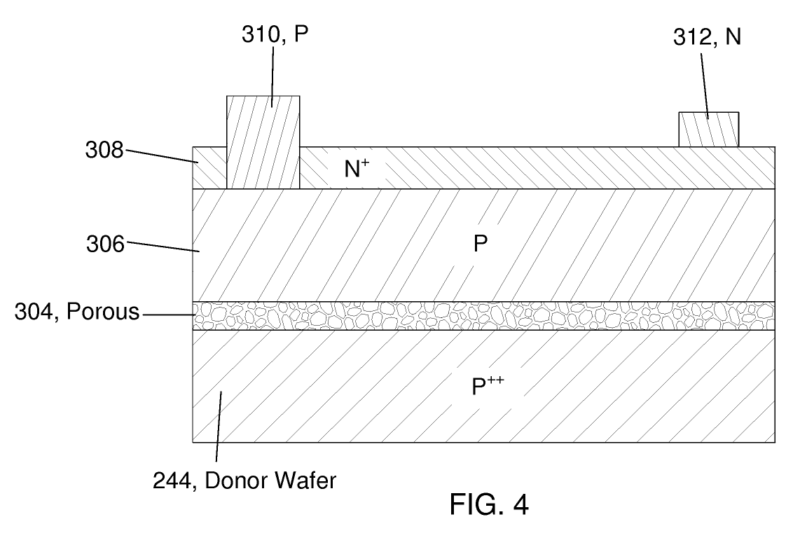

A schematic side cross-sectional view of a donor wafer 244 is shown in FIG. 4 with interdigitated backside contact PV cell structures formed on the upper surface of the donor wafer 244. In the illustrated embodiments, the donor wafer 244 is a heavily doped P⁺⁺-type monocrystalline silicon wafer. After the donor wafer 244 has been anodically etched in step 204 of FIG. 2 to form a porous silicon layer 304, which is crystallographically similar to the donor wafer 244 from which it is developed, the upper surface of the porous layer 304 is thermally smoothed. This smoothing process may be performed in a separate reactor, or just before the subsequent epitaxial silicon deposition. Further aspects of thermal smoothing are discussed in application Ser. Nos. 12/290,582, 12/290,588, and 12/399,248.

Next, in step 206 of FIG. 2, a P-type layer 306 of silicon doped less heavily than the donor wafer 244 is epitaxially grown on top of the smoothed porous separation layer 304. The heavily doped P⁺⁺-type donor wafer 244 results in some of the boron of the porous layer 304 and the donor wafer 244 diffusing into the growing epitaxial layer, a process called auto-doping, to form a P⁺-P junction. An N⁺ layer 308 of heavily doped silicon of the opposite conductivity type is then epitaxially grown on top of the P-type layer 306. Since both the silicon layers 306, 308 may be epitaxially grown by chemical vapor deposition, the dopant profile across the N⁺-P junction may be precisely controlled by the process parameters within the epitaxial reactor as is familiar to those skilled in the art. V. Siva et al. describe aspects of the control of the epitaxial growth process in a high-throughput multi-wafer epitaxial reactor in co-pending U.S. patent application Ser. No. 12/392,448, filed Feb. 26, 2009, incorporated by reference herein.

Alternatively, the N⁺ layer 308 may be formed by diffusing N-type dopants into the P-type layer 420, for example, at 850° C. or by other means of introducing counter dopants.

At this point, the photovoltaic structure of the individual solar cells has been established. It is advantageous to bin the many donor wafers 244 required for a solar cell panel. Binning involves testing the photovoltaic characteristics of an individual cell, for example, measuring its open circuit voltage V_{OC} of each solar cell while still attached to its respective donor wafer 244 and sorting them into respective bins according to the measured photovoltaic characteristics falling into the range associated with each bin. In assembling multiple solar cells into a panel, it is advantageous to assemble them according to the measured photovoltaic characteristics. The open circuit voltage of solar cells connected is parallel is limited by the minimum of the open circuit voltages of all the parallel solar cells. A similar limitation applies to photocurrents of solar cells connected in series.

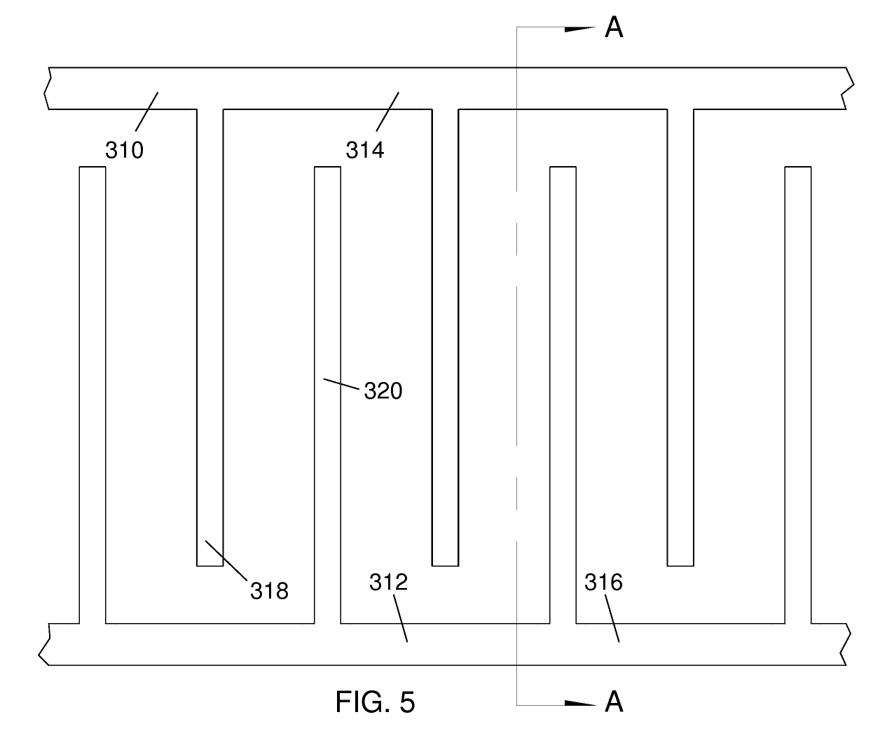

After growth of the N⁺ layer 306, in step 208, the IBC cells are partially built on respective ones of the donor wafers 244. A multiplicity of holes are formed through the N⁺ layer 308 to enable P⁺ diffusions 310, for example of boron to be formed for the interdigitated structure with appropriate sidewall isolation to the N⁺ layer 308, such as gaps in the N⁺ layer 308 adjacent the P⁺ diffusions 310. A second set of N contacts 312 connect with the N⁺ layer 804. The sectioned view of FIG. 4 is taken along the section line A-A of the plan view of FIG. 5. As explained in Ser. No. 12/290,582 and illustrated in FIG. 4, the contacts 310, 312 are formed of respective relatively wide bus bars 314, 316 and attached traces or fingers 318, 320 extending perpendicularly therefrom in an interdigitated pattern. Multiple sets of traces 318, 320 may extend from opposed sides of multiple bus bars 314, 316 in order to reduce the resistive loss in the traces. The widths and spacings of the bus bars 314, 316 and their traces 318, 320 may have a significant impact on the performance of PV cell array and are not limited by the illustrated relative widths. As explained in Ser. No. 12/290,582, the contacts 310, 312 may be formed at least partially of printed silver paste, which is then annealed to form conductive silver.

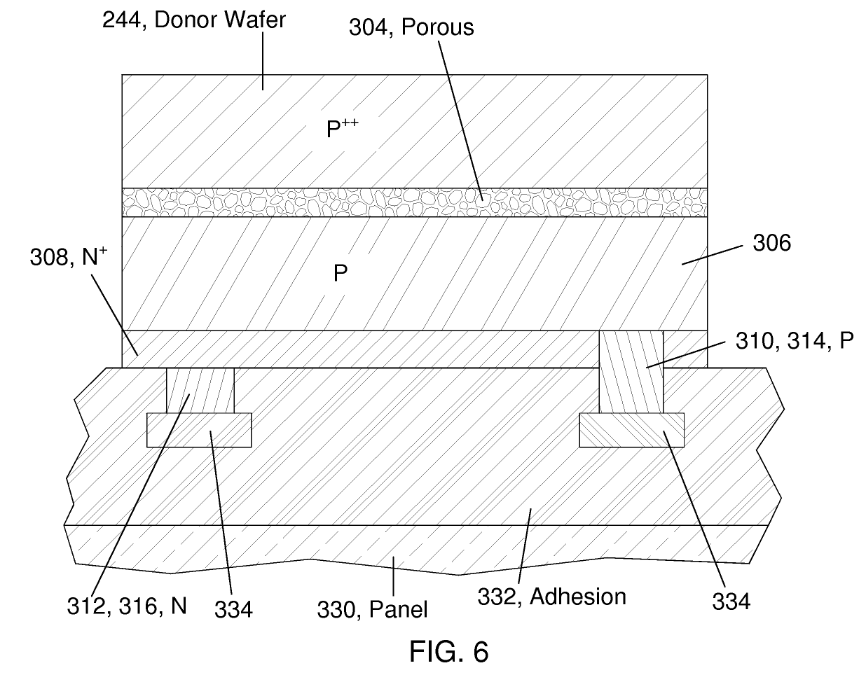

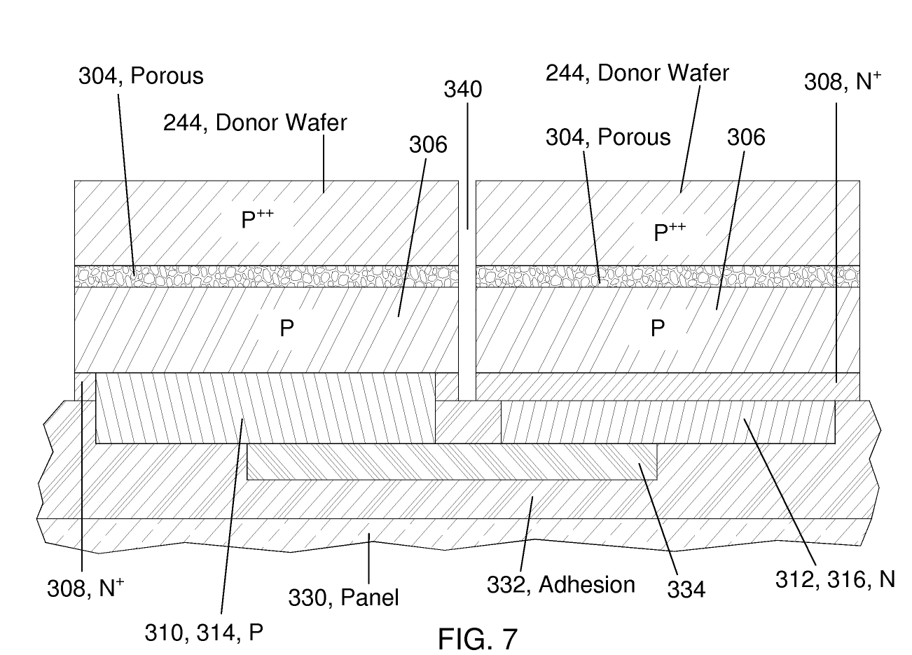

Two process steps are illustrated in the cross-sectional views of FIGS. 6 and 7 taken along perpendicular view lines. These figures also have their vertical orientations inverted from that of FIG. 4. The process steps include (1) tabbing and stringing of a linear array of the donor wafers 244 from FIG. 4, corresponding to step 208 of FIG. 2, and (2) attachment of the string of donor wafers 244 to a panel substrate through an adhesion layer, corresponding to step 210. In this embodiment, the two steps 208, 210 are combined. A panel substrate 330, for example, of glass, fiberglass, or Tedlar, is covered with an adhesive layer 332, for example, a sheet of ethyl vinyl acetate (EVA). Tedlar is available from DuPont and is the tradename for what is described as being composed of polyvinyl fluoride (PVF). EVA is also available in several grades from DuPont in thin easily handled sheets but when properly annealed at a melting temperature generally above 200 C flows and at yet higher temperatures cures to form a rigid but transparent adhesive polymeric plastic. However, other adhesion materials may be used and a high-temperature one is desired to allow higher temperature processing after curing of the adhesion layer. Alternatively, the panel 330 may be formed by flowing a resinous material onto the adhesion layer 332 to sufficient thickness that, when it is cured to a polymerizing temperature, it forms a thick and sturdy plastic layer capable of mounting the donor wafers 244.

For the conventional solar panel, neighboring PV cells are individually connected in series; thus, the P contact 310 from one donor wafer 244 will connect to the N⁺ contact 312 of the neighboring donor wafer 244. For such a serial connection, internal ribbons 334 are placed and aligned on the adhesion sheet 330.

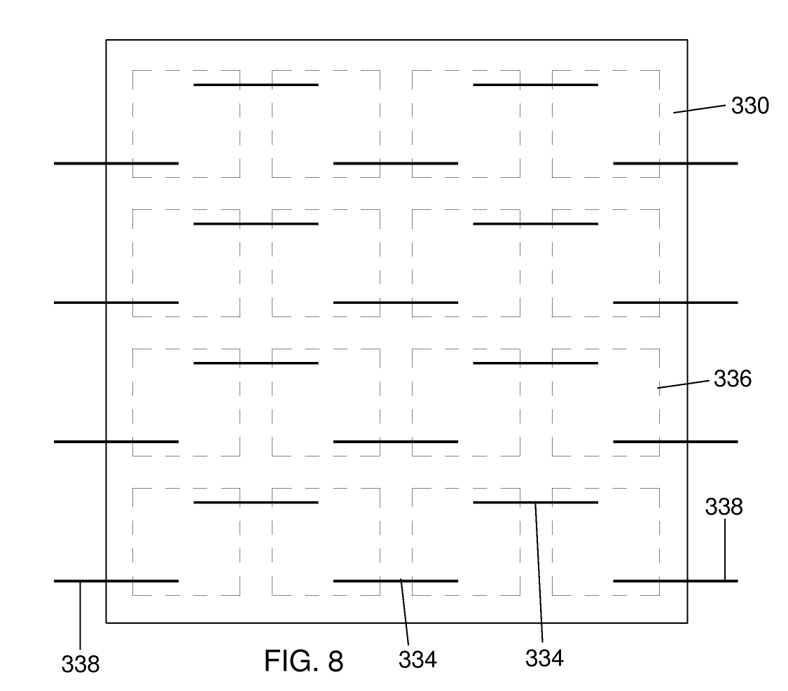

The internal ribbons 334 interconnect the serially connected cells and are typically relatively thin and flexible and are composed of a metal such as aluminum. In the serially connected IBC embodiment, the internal ribbons 334 may be placed on the EVA-covered panel substrate 330 in the general arrangement shown in the plan view of FIG. 8 to serially connect in multiple parallel strings an array of solar cells shown by dotted lines 336 and each associated with a separate donor wafer 244 at this point. External ribbons 338 may overlap the periphery of the solar cell array to allow external connection to the cells. The donor wafers 244 and attached P-N junction and contacts are placed on EVA layer 334 in alignment with the ribbons 332, 338 such that each internal ribbon 334 contacts the P-type contact 310 of one cell 336 and the N⁺⁺ contact 312 of one neighboring cell. The donor wafers 244 placed on the adhesion layer 332 are separated by a gap 340 of about 2 to 4 mm. In the case that the bus bars are at the lateral sides of the donor wafers 244, the neighboring ones of the serially connected solar cells 336 should have alternate 180 degrees rotations to allow easy connection between cells. On the other hand, if the bus bars are at the longitudinal ends, the same orientation may be maintained. Preferably, prior to placement of the donor wafers 244, silver paste dots are printed on the ribbons 334, 338 to facilitate bonding with the silver-paste contacts 310, 312. The ribbons 334, 338 preferably contact the wider bus bars 314, 316 or special widened pad areas of the contacts 310, 312.

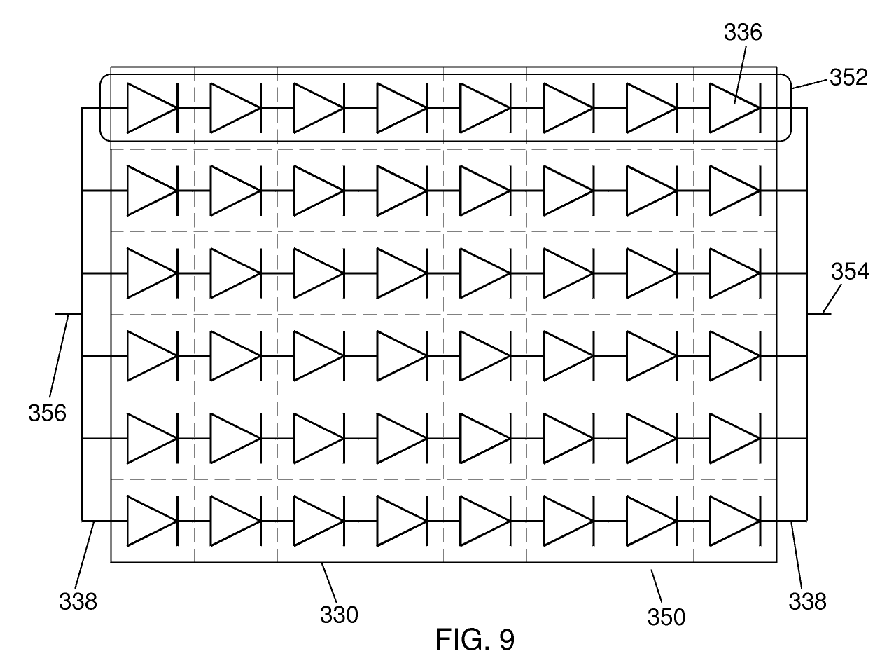

In the preferred embodiments, as exemplified in FIG. 8, multiple linear arrays of serially connected solar cells 336 are concurrently developed on the same panel substrate 330 by bonding multiple donor wafers 244 on the panel substrate 330 in a two-dimensional array, delaminating or separating the donor wafers 244 from their associated solar cells 336, which are still attached to the panel substrate 330, and then completing the processing on all of the solar cells 336 assembled on the panel substrate 330. As illustrated in the schematic electrical diagram of FIG. 9, the multiple series are connected in parallel on the edges of the panel substrate 330 to form a solar cell panel 350 of multiple serially connected linear arrays 352 connected together in parallel through their external strings 338 to a common anode 354 and a common cathode 356, which are connected via further power conditioning equipment to provide solar power to the electrical grid. In this arrangement, the binning may either involve selecting all solar cells in the panel to have similar photovoltaic characteristics, for example, open circuit voltages within a predetermined range, or selecting and assembling them such that the sum of open circuit voltages for all solar cells 336 in each string 352 is the same or nearly the same, within some range, for all the strings 352.

The string-adhesion-substrate stack of FIGS. 6 and 7 is then thermally laminated together in a process familiar to those skilled in the art such as autoclaving at an elevated temperature, for example, above 125 C or above 220 C for the previously described EVA inside a vacuum-evacuated bag. During this lamination process, the adhesion layer 332 melts and flows around the ribbons 334 and also bonds to the upper surface of donor wafers 244 and their backside contacts 310, 312. At some point during the processing, the adhesion layer 332 hardens into a rigid structure holding the ribbons 334 in place. During the lamination, the ribbons 334 may be pushed against the panel substrate 330. Further, the heights of the P and N contacts 310, 312 may be different but the respectively applied ribbons 334 are held in the flowing and then hardened adhesion layer 332.

The lamination process of the first embodiment thus both bonds the PV cells to the mounting substrate but also attaches all sets of the required inter-cell backside interconnects.

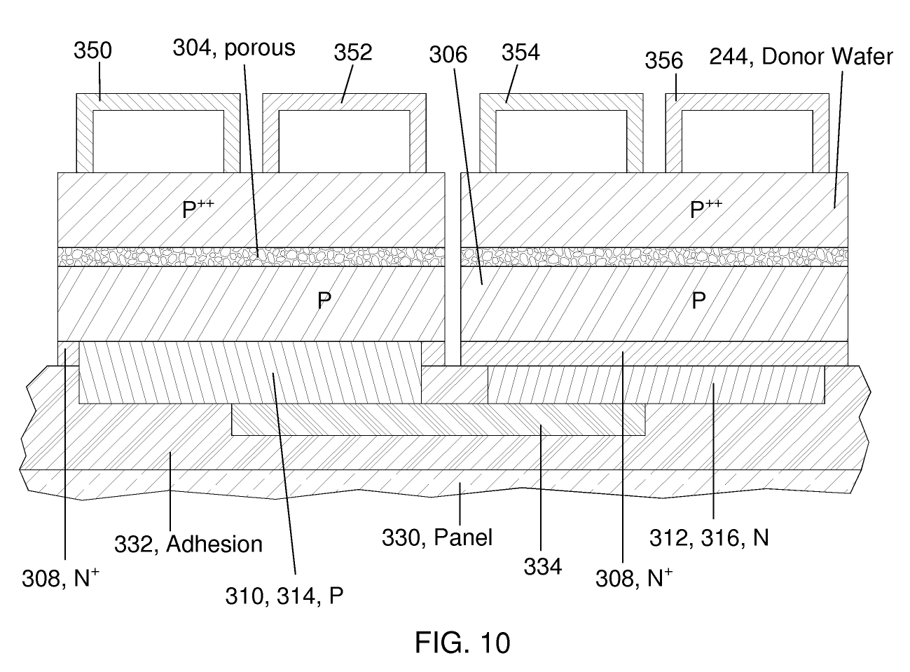

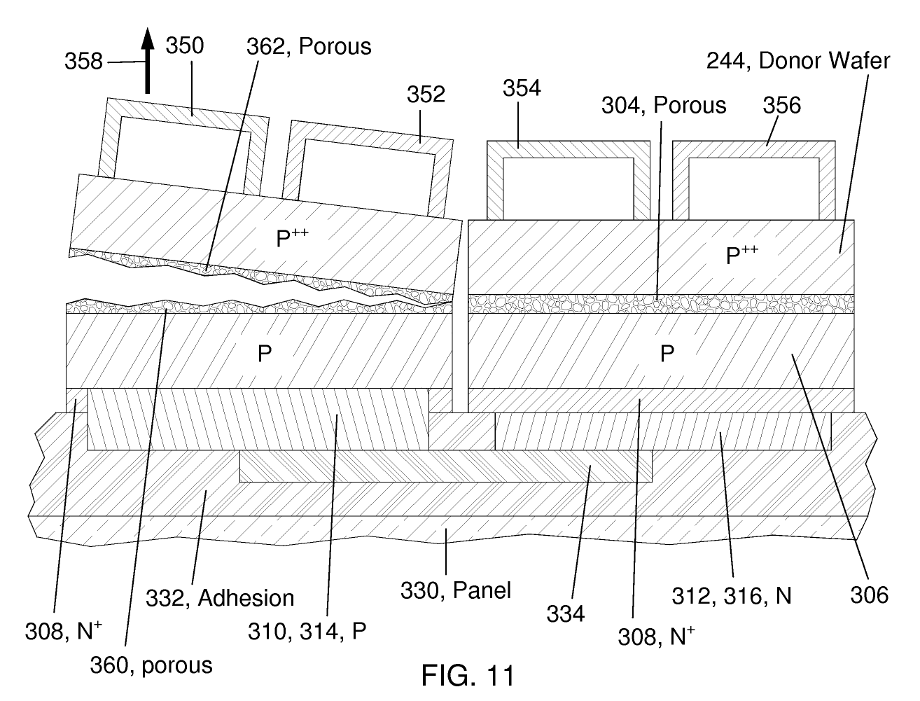

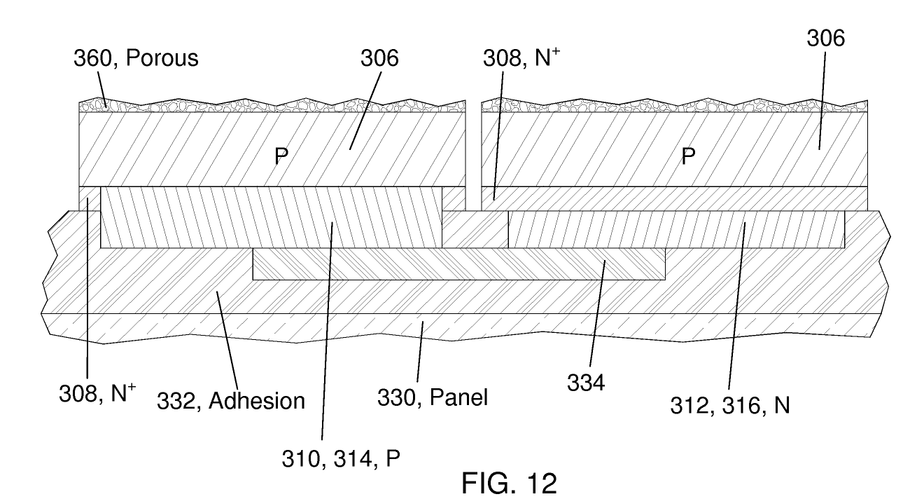

The cross-sectional views of FIGS. 10-12 illustrate the exfoliation or separation process corresponding to step 212 of the first process embodiment of FIG. 2. In FIG. 10, a wafer chuck assembly, comprising individual clamping elements 350, 352, 354, 356, is attached to the upper surfaces of multiple donor wafers 244 in the laminated assembly formed in FIGS. 6 and 7. The clamping elements 350-356 may be separately actuatable electrostatic or vacuum elements or other effective clamping means. Note that in this embodiment the upper, light-receiving surfaces of the donor wafers 244 are on the sides of the donor wafers 244 closest to what will become the front sides of the completed PV cells. In FIG. 11, the exfoliation or separation process has begun, starting at the left, where arrow 358 represents an upward pulling force on the first clamping element 350. Ideally, an upward force 358 applied to the leftmost, first clamping element 350 is accompanied by an additional torquing force on the first clamping element 350 (clockwise in FIG. 11) to aid initiation of separation at the leftmost edge of the porous layer 304, where the porous layer 304 is separating into a lower porous layer 360 (attached to the P-type layer 306) and an upper porous layer 362 (attached to the P⁺⁺-type donor wafer 244). It is preferred that the exfoliation of the donor wafer 244 be accomplished by a gradually developing separation of the two parts. The exfoliation process preferably proceeds sequentially, towards the right in FIG. 11 and also in the transverse direction for a two-dimensional array, so that the donor wafers 244 are sequentially separated from the PV cell structures at the bottom of FIG. 11. However, it is also possible to simultaneously exfoliate multiple donor wafers 244, whether for small groups, for a sequence of rows or columns in the two-dimensional array or for the two-dimensional array as a whole eventually leading to FIG. 12, where all the donor wafers 244 have all been exfoliated and the partially developed solar cells are all attached to the panel substrate 330. Chemical etch exfoliation processes are known and may be used alone or in combination with the mechanical exfoliation process illustrated in FIGS. 9-11.

Following exfoliation, all of the donor wafers 244 can be etched to remove the upper residual porous layers 362, and subsequently returned to block 202 in FIG. 2 for reuse.

From this point on, the epitaxial PV thin films remain attached to the back mounting substrate. As a result, the PV thin films are always attached to either the donor wafers, the backside mounting substrate, or both and are never handled as free-standing thin films.

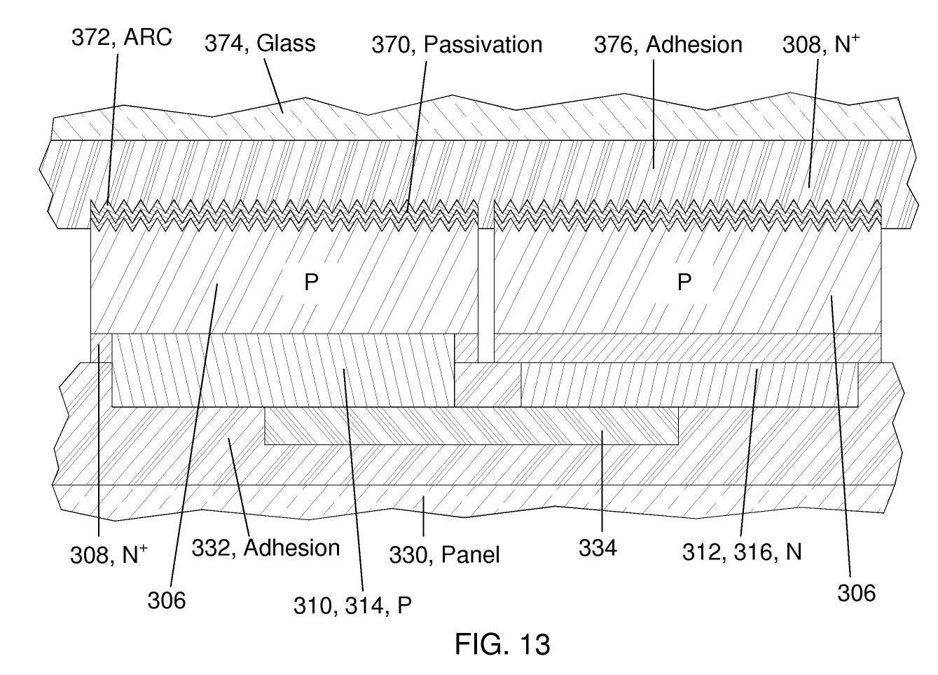

FIG. 13 is a schematic side cross-sectional view of the solar cell array from FIG. 12 after completion of the remaining frontside fabrication steps, corresponding to steps 214, 216 of FIG. 2, simultaneously performed on all the donor wafers 244 attached to the panel substrate 330: (1) etch removal of the lower residual porous layers 360 of FIG. 11, (2) texturing of the upper surfaces of the P⁺-type layers 306, (3) deposition of passivation layers 370, (4) deposition of anti-reflective coatings (ARC) 372, and (5) attachment of a frontside glass layer 374 using an adhesion layer 376, for example, of EVA. Because of the lower adhesion layer 332, all subsequent processing steps must be conducted at relatively low temperatures (below the melting point of the adhesion layer, which for EVA is approximately 220 C). The frontside glass layer 374 must transmit the solar radiation to the PV cells so it should be transparent. By transparent is meant having an optical transmission of at least 50% of solar radiant energy, preferably 90% or 95% and greater.

The residual porous layer 360 of FIG. 12 can be removed from the PV cells in an etching process in step (1) using a wet-etch process familiar to those skilled in the art. The etch rates of silicon are highly dependent on its porosity. The porous silicon layer 360 will etch much faster than the dense silicon of the epitaxially grown P-type layer 306. Note that this etch removal process must be compatible with the adhesion layer 330, which may be exposed to the corrosive liquid and vapor of the silicon etch environment.

Texturing of the P-type layer 306 to form its upper corrugated surface is also a process familiar to those skilled in the art. Again, this texturing process must be compatible with the plastic adhesion film 332, which places both chemical resistivity and temperature limitations on the choice of texturing process. Following texturing in step (2), the passivation layer 370 is deposited on the upper (now textured) surface of the P-type layer 306. Note that it is generally not possible to grow the passivation layer 370 using oxidation since such processes require high temperatures which would damage the lower adhesion layer 332. Thus, a sputtering or evaporation process for deposition of passivation layer 370 may be used; for example, sputter deposition of silicon nitride is one possibility. In step (4), the anti-reflecting coating (ARC) 372 is deposited on top of the passivation layer. This process must also be compatible with the chemical resistivity and temperature range of the lower EVA adhesion layer 332. Finally, in step (5), the frontside glass layer 374 is attached to the PV cell array using the second, upper adhesion layer 376, preferably of EVA applied in sheet form and thereafter laminated, for example, by the previously described auto-claving, producing the completed PV cell array shown in FIG. 13.

The upper adhesion layer 376 should perform several functions, which are satisfied by ethyl vinyl acetate (EVA), which is commercially available from DuPont. However, other low-temperature glasses may be substituted. For use as an adhesion layer, the material of the adhesion layer should adhere to the layers above and below it and should flow into the parts, but it preferably hardens to its final form. For use as an encapsulant protecting the semiconductor device, it should flow but in its final form should be hard and impermeable. EVA can be characterized as a polymer which thermally sets to a plastic at a readily identifiable hardening temperature typically in the range of 200 to 300 C. However, temperatures for other subsequent processing steps should be limited to the hardening temperature. On the light-receiving side of the device, it should be transparent and index matched between the frontside glass and the anti-reflective coating. Thermally set EVA has been found to be transparent and to have satisfactory optical properties.

The external ribbons 338 of FIG. 8 are then connected at the periphery of the panel 330 to form the solar cell panel circuit of FIG. 9.

The first embodiment has the advantage of a frontside surface free of electrodes, thus increasing the light gathering efficiency of the solar panel.

### Second Embodiment

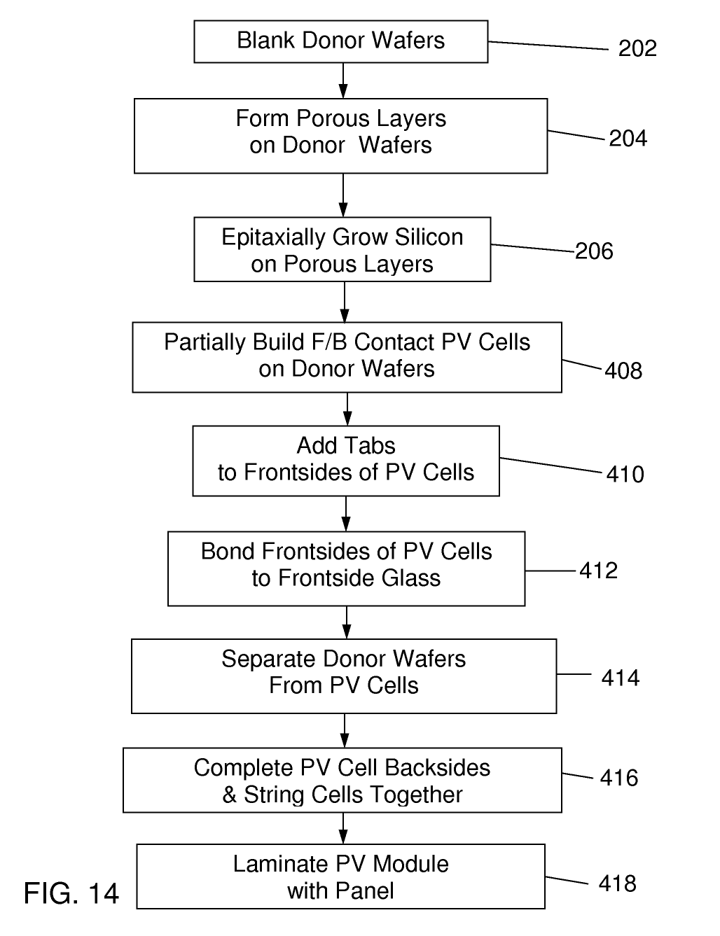

A flow chart shown in FIG. 14 outlines a second process embodiment of the present invention for manufacturing a solar panel utilizing PV cells with frontside/backside connections and tabbing and stringing. A multiplicity of blank donor wafers supplied in block 202 are anodically etched in step 204 to form porous separation layers on the upper surfaces of the respective donor wafers as described above. In step 204, silicon is epitaxially deposited on the porous silicon layer. In step 408, a multiplicity of frontside/backside contact PV cells are partially formed using processing steps as described in aforecited application Ser. No. 12/290,588. The PV cells from step 408 are then tabbed to the frontside contacts in step 410, followed in step 412 by attachment to a frontside glass layer using an adhesive layer. The backsides of the donor wafers in the PV cell array formed in step 412 are next clamped to a flexible chuck assembly and exfoliated to separate the PV cell array from the donor wafers. The PV cell backsides are now completed in step 416 using only low temperature processes compatible with the adhesion layer, for example, of EVA, used to attach the frontside glass layer in step 412, followed by stringing together of the PV cells. Finally, in step 418, a backside substrate is attached to the PV cell array using a second adhesion layer.

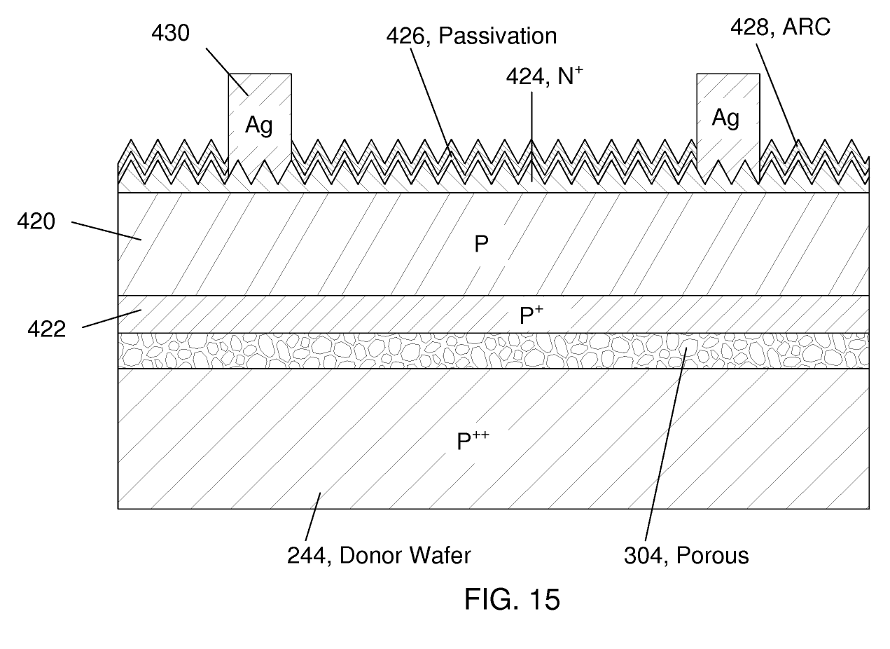

A schematic side cross-sectional view of FIG. 15 illustrates a donor wafer 244 with frontside PV cell structures formed on an upper surface. First, corresponding to step 204 in the second process embodiment of FIG. 14, the porous layer 304 is formed by anodically etching the donor wafer 244 in the anodic etching tank 220 of FIG. 3 or similar equipment. The upper surface of the porous layer 304 is thermally smoothed as described in the first embodiment. Next, corresponding to step 406 of FIG. 14, a P-type layer 420 of silicon is epitaxially grown on top of the porous layer 304. The high temperature epitaxial growth process for the P-type layer 420 may induce autodoping of the lower portion of the P-type layer 420 to form as a more highly doped P⁺-type layer 420. Autodoping is a thermal diffusions process that occurs when dopants from the very highly doped P⁺⁺ donor wafer 244 and its porous layer 304 to diffuse up into a thin region of the bottom of the P-type layer 420 as it is being grown epitaxially on top of the porous layer 1002. Autodoping is familiar to those skilled in the art. If the P⁺-type layer 420 has a thickness of 2 to 3 microns and a resistivity of less than 0.5 ohm-cm, it provides an effective electron mirror to reflect electrons reaching the P⁺-P junction.

A highly doped N⁺ layer 424 of silicon is then epitaxially grown on top of the P-type layer 420. More generally the layers 424, 420 are of opposite conductivity types. Since both layers 420, 424 are epitaxially grown with the appropriate dopant type and dopant concentration of CVD precursors, the dopant profile across the N⁺-P junction formed at the boundary of layers 420, 424 may be precisely controlled by the process parameters within the epitaxial reactor as is familiar to those skilled in the art. Aspects of the control of the epitaxial growth process in a high-throughput multi-wafer epitaxial reactor are in afore cited application Ser. No. 12/392,448. Alternatively the N⁺ layer 424 may be diffused into or otherwise formed in the P-type layer 420 as described for the first embodiment.

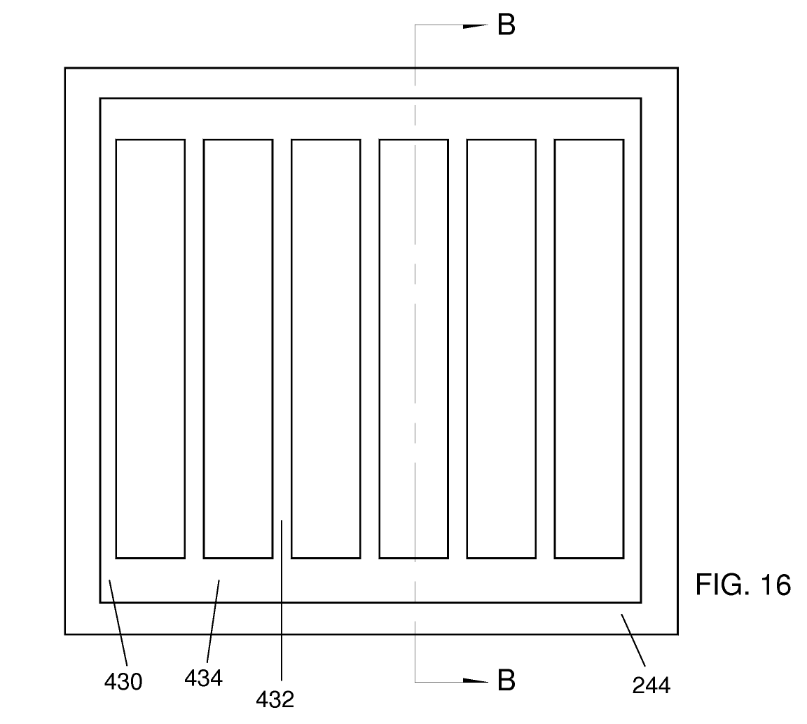

After growth of the N⁺ layer 424, in step 408, the upper surface of the N⁺ layer 424 is textured using a standard texturing process as is familiar to those skilled in the art. A passivation layer 426 is conformally formed over the textured upper surface of the N⁺ layer 424 either by growth by thermal oxidation of the N⁺ layer 424 or deposited over it by sputtering or evaporation. At this point in the fabrication process for the solar array, high temperature processes for formation of passivation layer 426 are allowable. An anti-reflection coating (ARC) 428, for example, of silicon dioxide or silicon nitride is conformally deposited on top of the passivation layer 428. Different combinations of materials may be chosen for the passivation and anti-reflective layers 426, 428. Next, as shown in FIG. 15 and corresponding to the end of step 406, silver (Ag) contacts 430 are deposited on top of the ARC layer 426, typically by printing of silver paste. The cross-sectional view of FIG. 15 is taken along section line B-B of the plan view of FIG. 16 showing the layout of the contact 430, which are used for frontside contacts and are preferably deposited as a grid of narrow traces 432 connected on each end to two wider and perpendicularly arranged busbars 434 in a fence-like structure of rails and slats. The contacts 430 illustrated in FIG. 15 correspond to the bus bars 434. The silver-paste contacts 430 printed over the anti-reflection layer 428 are subjected to a high temperature sintering step which converts the paste to silver and drives the silver through the ARC and passivation layers 428, 426 to create ohmic contacts between the Ag contacts 430 and the N⁺ layer 424. The partially completed PV cells formed at this point may be used for either the second or third embodiments of the present invention.

Binning may advantageously be performed on the individual solar cells of FIG. 15 while still attached to their respective donor wafers 244, as was described for the first process embodiment. In the present second process embodiment, the binning also takes into account any variation in the texturing and passivation and anti-reflection layers 426, 428. The selection from the bins may be uniform for the entire array or may produce a common distribution of the performance characteristic for each the serial strings, which are eventually connected in parallel.

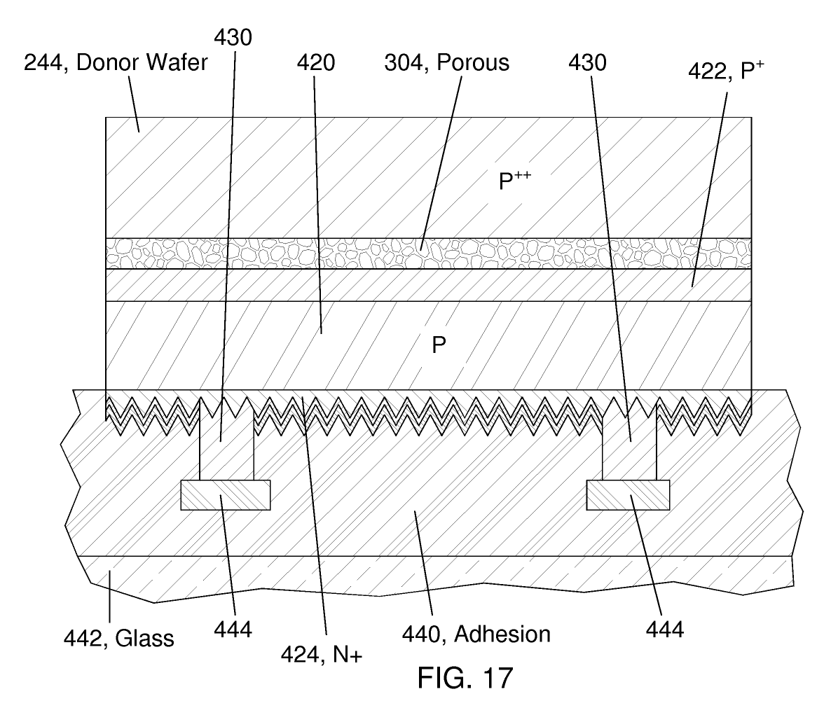

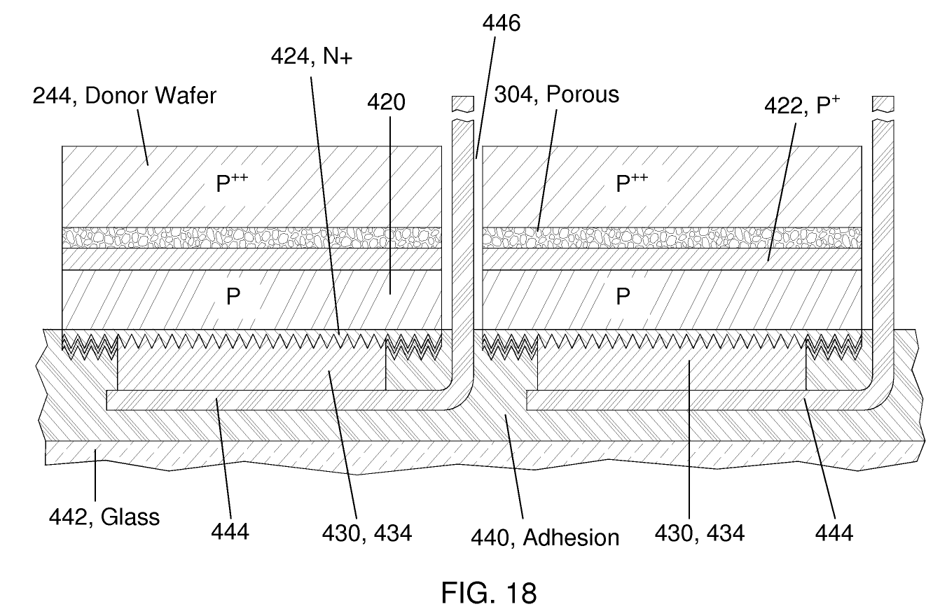

Two process steps are illustrated in the cross-sectional view of FIG. 17 taken across the bus bars 434 along the section line B-B of FIG. 16 and the perpendicularly arranged cross-sectional view of FIG. 18 taken along the bus bars: (1) tabbing of the frontside contacts on the donor wafers 244 from FIG. 15, corresponding to step 410 of FIG. 14 and (2) attachment of a multiplicity of tabbed donor wafers 244 to a frontside glass layer through an adhesion layer, corresponding to step 412. However, these steps may be intertwined.

An adhesion layer 440, for example, a sheet of adhesive-forming material, such as EVA, is laid over a frontside glass substrate 442. Ribbons 444 are laid over the EVA adhesive layer 440 in a pattern to underlie and extend along the busbars 434 of the Ag contacts 430 but are bent up at the ends, as shown in FIG. 18, beyond a side of the intended locations of the donor wafers 244 to a height above what will become the backside of the PV cells. Silver-paste dots may be printed on the horizontal portions of the ribbons 444 to aid attachment.

The donor wafers 244 are placed over the adhesion layer 440 with the busbars 434 of their Ag contacts 430 aligned with the horizontal portions of ribbons 444 and with their vertically ascending ends accommodated within a gap 446 between neighboring ones of the donor wafers 244 but not touching either of the donor wafers 244.

The wafer-adhesion-glass stack is then thermally laminated together in step 412 of FIG. 14 in a process familiar to those skilled in the art, such as the previously described autoclaving. During this lamination process, the adhesive layer 440 softens and flows around the ribbons 444 and bonds with the textured front surface of the PV cell, and also bonds to the upper surface of the frontside glass layer 442 and to the contacts 330. The lamination temperature is also sufficient to harden the material of the adhesion layer 440 of EVA into a plastic or glass-like layer.

The lamination process of the second process embodiment thus not only bonds the PV cells to the frontside glass but also attaches one set of ends to the inter-cell interconnects.

The exfoliation process for step 414 of the second embodiment of FIG. 14 follows that illustrated in FIGS. 9-12 and will not be repeated in detail.

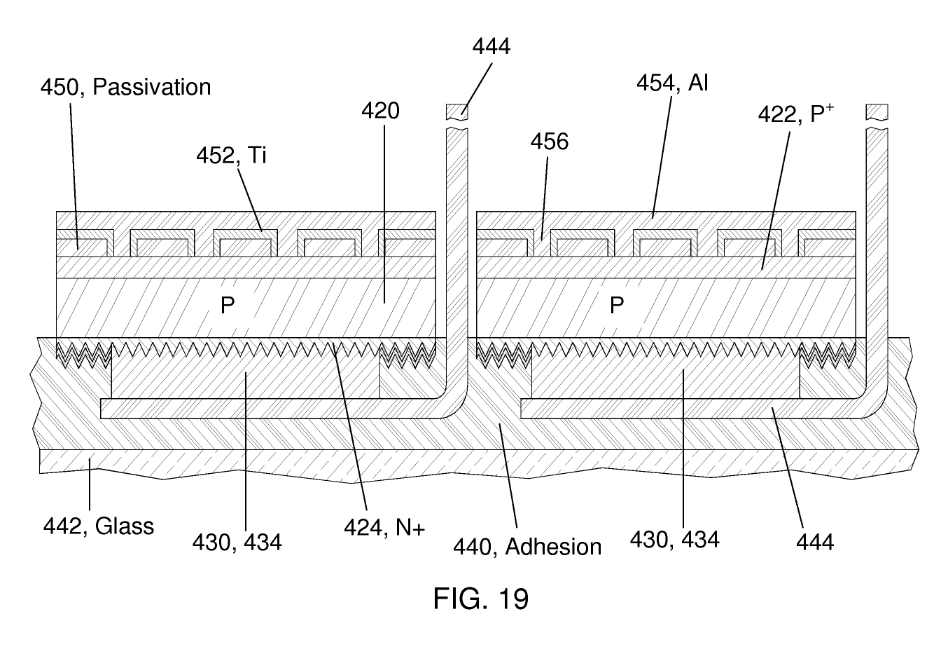

FIG. 19 is a schematic side cross-sectional view of the solar cell array of FIGS. 17 and 18 along the direction of the busbars 434 after completion of the exfoliation step and the removal of the residual porous silicon to leave exposed P⁺ layer 420. The second process embodiment similarly to the first avoids handling free-standing PV thin films. Instead, the PV thin films are always attached to either the donor wafers or the backside panel or both. This figure further illustrates the structure after simultaneously completing the following backside fabrication steps corresponding to step 414 of FIG. 14 on all the PV cells bonded to the frontside glass layer 442: (1) deposition and formation of patterned passivation layers 450, (2) conformal deposition of titanium layers 452 on the passivation layers 450, and (4) deposition of aluminum layers 454 on top of the titanium layers 452 and down into contact openings 456 in the passivation layers 450 to make contact with the P⁺-type layers 422. Note that to avoid damaging the adhesion layers 440, all these steps and subsequent processing steps should be conducted at temperatures below the hardening point of the adhesion material such as EVA, for example, below 225 C. However, the processing of the corrugated frontside surface and its conformal coatings is not subject to this temperature limitation.

In step (1), the patterned passivation layers 450 are deposited on the upper surfaces of the P⁺-type layers 422, for example, silicon nitride to a thickness of about 70 nm. Note that it is generally not possible to grow the passivation layers 450 using oxidation since such processes require high temperatures which would damage the EVA adhesion layer 440. Thus, a sputtering or evaporation process for deposition of passivation layers 450 may be used; for example, sputter deposition of silicon nitride is one possibility. In step (3) thin titanium layers 452 are conformally deposited over the patterned passivation layers 450. This titanium deposition process has the same temperature constraints that applied to deposition of the passivation layers 450. Finally, in step (4), aluminum layers 454 are deposited over the titanium layers 452 and also into the contact openings 456 in the passivation layers 450. The aluminum layers 454 thus make contact with the P⁺-type layers 422. The patterning of the passivation layers 450 should maximize the area of the passivation layers 450 to reduce any backside leakage while allowing sufficient width for the contact holes 456 to allow low resistance contacts between the aluminum layer 454 and the P⁺-type layers 422.

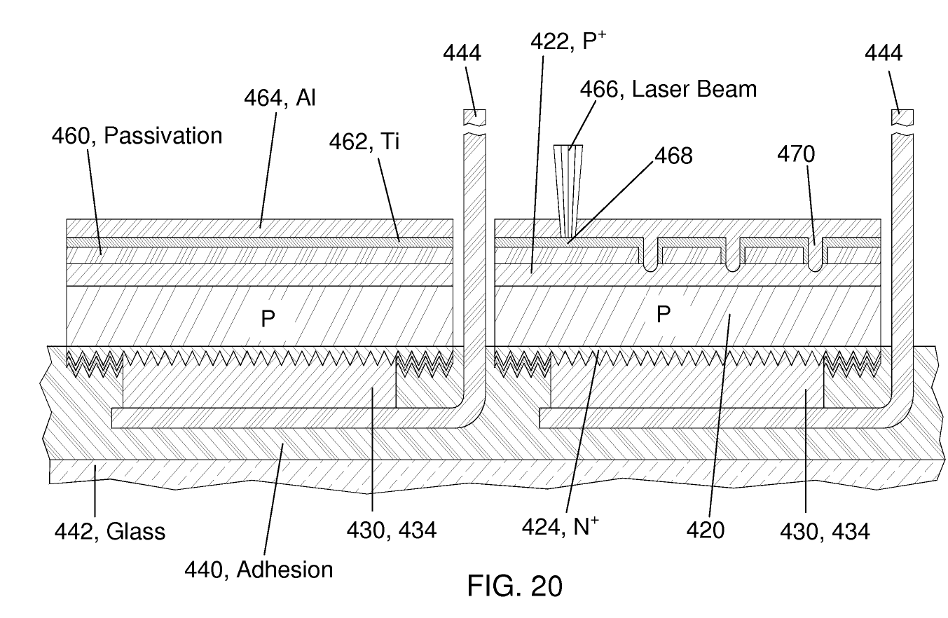

The schematic side cross-sectional view of FIG. 20 illustrates an alternative processing of fabricating the aluminum contacts in the solar cell array of FIG. 19. The alternative process includes deposition of an unpatterned passivation layer 460, an unpatterned titanium layer 461, and an unpatterned aluminum layer 464. A focused laser beam 466 irradiating the aluminum layer 460 and its underlying layers 462, 460 melts the aluminum in selective areas 468 and dissolves the underlying titanium and passivation to form contacts 470 through the passivation layer 460. The same thermal considerations apply to the process of FIG. 20 as apply to FIG. 19 due to the polymeric adhesion layer 440. An advantage of the process in FIG. 20 may be improved ohmic contact between the aluminum layers 464 and the P⁺-type silicon layers 422, as well as eliminating the need for separate patterning of the passivation layers 460 and thus allowing a simpler unpatterned passivation layer to be deposited. At the right, three contacts 470 can be seen to have just been formed by the laser beam 466, which is steered across the backside surfaces of the PV cells using standard laser beam deflection methods familiar to those skilled in the art. Note that the contacts 470 may penetrate below the planes of the upper surfaces of the P⁺-type layers 422.

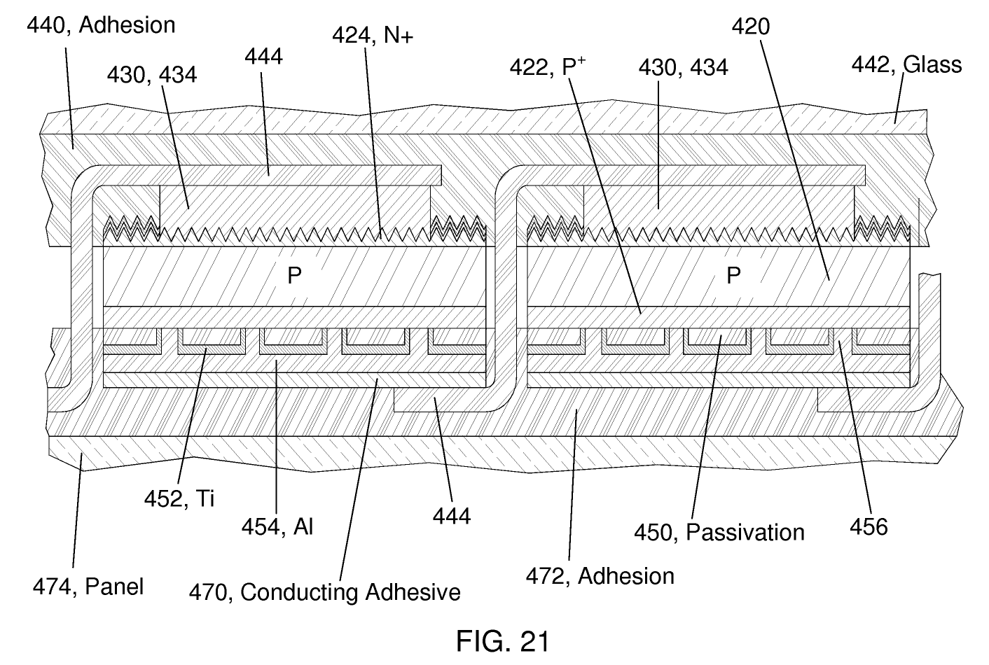

The schematic side cross-sectional view of FIG. 21 illustrates the solar cell array from either FIG. 19 or 20 shown after simultaneously completing the following fabrication steps corresponding to steps 414, 416 of FIG. 14 on all the PV cells bonded to the frontside glass layer 442. The vertical orientation of FIG. 21 is inverted from that of FIGS. 19 and 20. The process includes: (1) deposition of conducting adhesive layers 470 on the backsides of the PV cells, (2) stringing of the PV cells, and (3) attachment of a backside panel using an adhesion layer. Again, these steps may be intertwined.

In one exemplary process sequence, a conductive adhesive layer 470 is applied over the aluminum layer 454 (or 464 of FIG. 20). The exposed ends of the ribbons 444 are bent over to contact and be adhered to the conductive adhesive layer 470. The ribbon bending is the direction to electrically connect the contact 430 of one cell to the aluminum layer 470 of the neighboring cell.

Separately, a backside adhesion layer 472 is applied to a panel substrate 474. The panel substrate 474 may be glass or more preferably Tedlar. The adhesion layer 472 may be formed by laying a sheet of adhesion material such as EVA on the panel substrate 474. Then, the array of solar cells attached to the frontside glass 442 with the cells interconnected by the ribbons 440 is placed on the backside adhesion layer 470. The glass-adhesion-wafer-adhesion-substrate stack is then laminated together thermally in a process familiar to those skilled in the art such as the previously described autoclaving. During this process, the adhesion sheet 472 melts and flows around the ribbons 444 and bonds to them and to the conducting adhesive layer 470, and also bonds to the upper surface of the panel substrate 474.

Alternatively, the panel 330 may be formed by flowing a resinous material onto the adhesion layer 472 to a sufficient thickness that, when it is cured at a polymerizing temperature below the melting point of the adhesion layers 440, 470, it forms a rigid and sturdy support.

The previously described FIG. 9 is an electrical schematic diagram of a solar panel 350 according to the first and second embodiments of the present invention. Each PV solar cell 336 is represented as a diode with several, N of PV cells connected in series to form strings 352, each string 352 having an output voltage equal to the sum of the photovoltaically-generated voltages of the N PV cells 336 of that string 352. In the prior art, often M strings 336 each containing twelve PV cells 352 are typically used (only eight are illustrated here), for example, M=6 strings 352 connected in parallel in the finished solar panel 350. At the left of FIG. 9, six strings 352 are shown with a parallel electrical connection 356, while at the right of FIG. 9, six strings 352 are shown with a parallel electrical connection 354. Thus, for the overall solar panel 350, the output voltage will be proportional to the number N of the cells 336 in each string 352 or at least the sum of the output voltages of the cells 336 in the string 325. The output current will be equal to the output current of a single string 352 times the number M of strings 352 wired in parallel by connections 354, 356 or at least the sum of the output currents of the M strings 352.

### Third Embodiment

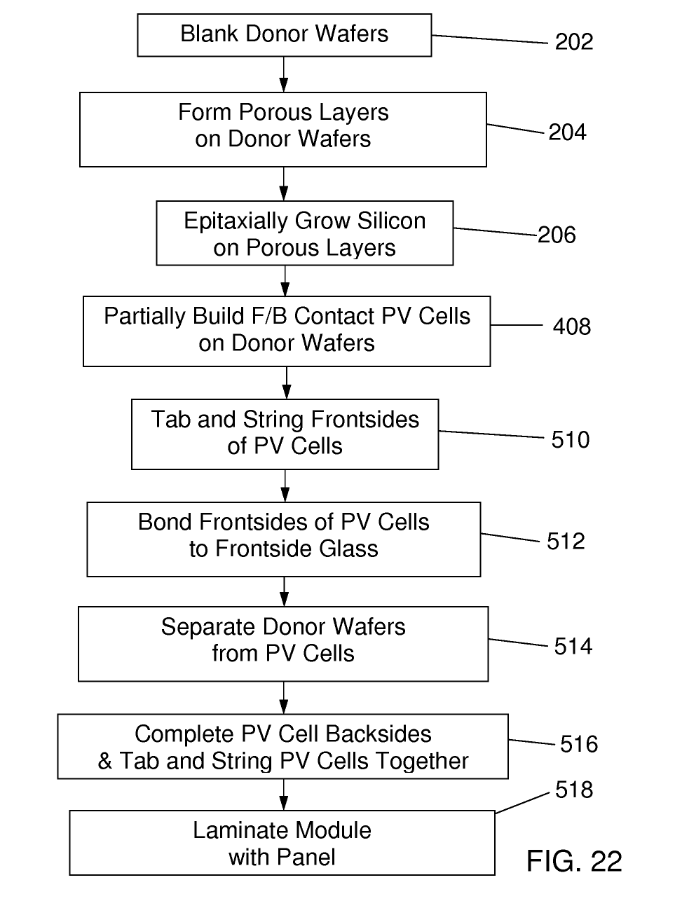

A flow chart shown in FIG. 22 outlines a third process embodiment of the present invention for manufacturing a solar panel utilizing PV cells with frontside/backside connections and unconventional tabbing and stringing. A multiplicity of blank donor wafers in block 202 are anodically etched in step 204 to form porous separation layers on the upper surfaces of the respective donor wafers 442 as described for the first embodiment. In step 206, silicon is epitaxially grown on the porous silicon layer. In step 406, a multiplicity of frontside/backside contact PV cells are partially formed using conventional processing steps as described in aforecited application Ser. No. 12/290,588 and described in detail in the second embodiment. In step 510, a linear array of the PV cells from step 408 are tabbed to the frontside contacts and strung together, followed by attachment in step 512 to a frontside glass layer using an EVA adhesive layer. The backsides of the donor wafers in the PV cell array formed in step 512 are next in step 512 clamped to a flexible chuck assembly and exfoliated from the PV cells partially formed on the frontside glass layer. The PV cell backsides are then completed in step 516 using only low temperature processes compatible with the EVA adhesion layer used to attach the frontside glass layer, followed by stringing together of the backsides of the PV cells. Finally, in step 518, a backside substrate is attached to the PV cell array using a second EVA adhesion layer.

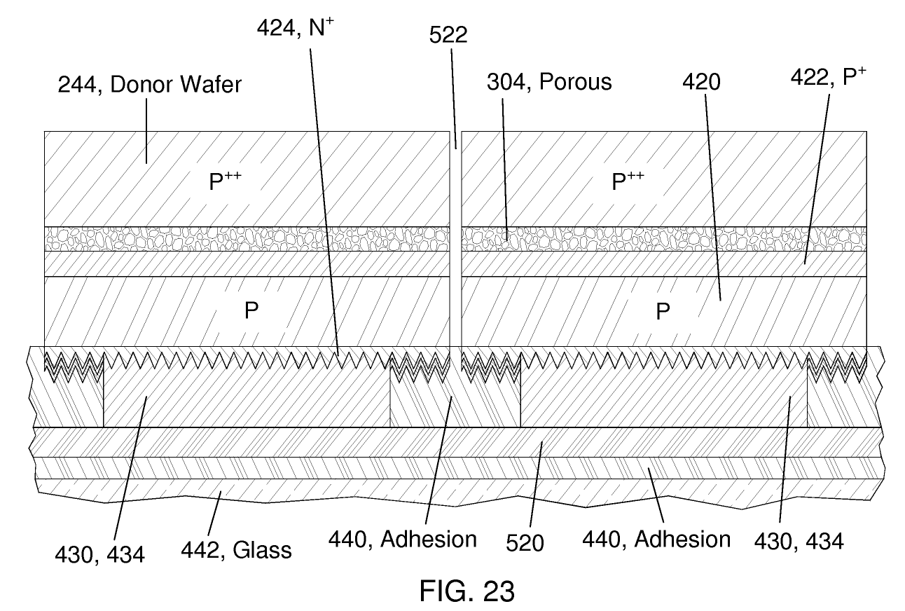

The cross-sectional view of FIG. 15 of the second embodiment shows the textured donor wafer 244 with its frontside contacts 430, which corresponds to end of step 408 in FIG. 22 of the third embodiment. The donor wafers 244 are individually tested for solar performance, for example, for open-circuit voltage V_{OC} and are accordingly binned according to performance. Plural donor wafers 244 may selected from the bins with a common performance since they will be connected in parallel for the illustrated string and assembled to form the structure illustrated in the cross-sectional view of FIG. 23. Two process steps are illustrated in FIG. 23: (1) tabbing and stringing of the frontside contacts on the donor wafers donor 244, corresponding to step 510 of FIG. 22, and (2) attachment of the strung donor wafers 244 to the frontside glass layer 442 through the EVA adhesion layer 440, corresponding to step 512. Once again, these steps are intertwined.

In one process, the adhesion sheet, for example of EVA, to form the adhesion layer 440 is laid on the frontside glass 442 and long ribbons 520 are placed on the adhesion sheet 332 to interconnect the P-contacts 430 of a number of neighboring cells in a parallel connected string. Plural donor wafers 244 are placed on the adhesion sheet 440 with gaps 522 between them and aligned such that the bus bars 434 of a linear array of donor wafers 244 are aligned with the one or more ribbons 520 for that array. The stacked assembly of donor wafers 244, P-N junctions, frontside contacts, adhesion sheet, and frontside glass 442 are thermally laminated to cause the adhesion material to flow around and under the ribbons 520, harden, and adhere to the ribbons 520, the P-contacts 430, especially their traces, and the frontside glass 442.

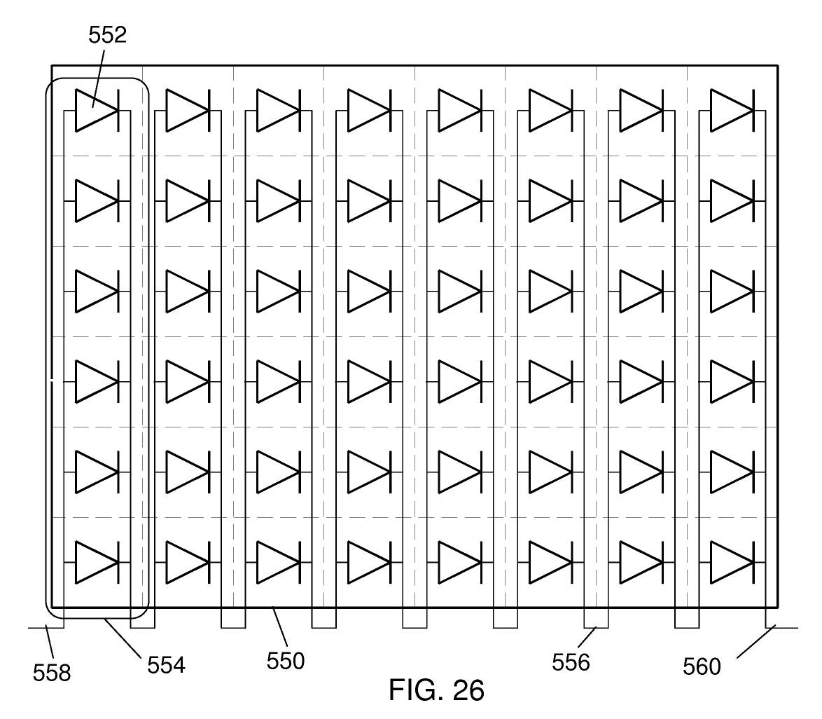

In the previously described second process embodiment of FIG. 21, a conventional back-to-front stringing technique was employed, resulting in the PV cells of each string being wired in series. On the other hand, for the third process embodiment of FIG. 23, the method of stringing is different. For each PV cell, each of the frontside N⁺ contacts 430 on each PV cell is strung together to a corresponding one of the frontside N⁺ contacts 430 on all of the other PV cells in the horizontally or parallel arranged string. Since typically each PV cell has more than one bus bar, more than one ribbon 520 may be used to string all the PV cells together along the length of the string. The term “stringing” is used here in a physical sense rather than electrical sense of interconnecting. The stringing of FIG. 13 of the first embodiment results in a serial electrical interconnection while the stringing of FIGS. 22 and 26 results in a parallel electrical interconnection. The net result of this novel method of stringing is that all the PV cells in each string are wired in parallel, not in series as is conventionally done. Further details of the electrical schematic for the overall solar array are provided in the schematic electrical diagram of FIG. 28 presented below.

The string of donor wafers 244 is now positioned, corresponding to step 512 of FIG. 22, with the P-contacts 430 of the PV cells facing downwards on the top of the EVA adhesion layer 520 with the bus bars 434 of all the PV cells in the linear array aligned with the one or more ribbons 520. The wafer-adhesion-glass stack is then thermally laminated together in a process familiar to those skilled in the art such as the previously described autoclaving. During this lamination process, the adhesion layer 440 melts, flows around the ribbons 520, and hardens to bond to the textured surface of the PV cells, and also bonds to the upper surface of the frontside glass layer 442.

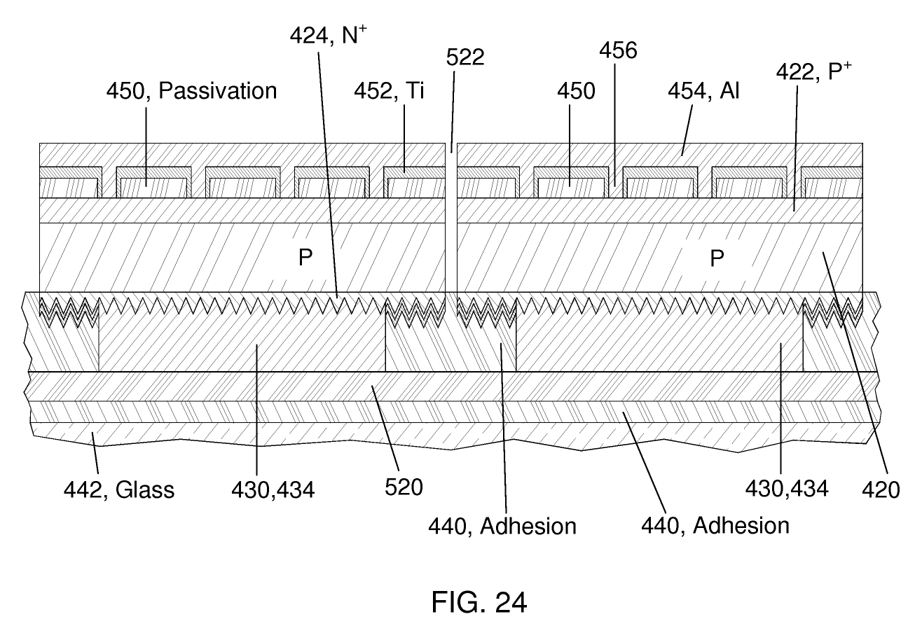

The exfoliation process for step 514 of the third embodiment of FIG. 22 is generally follows the exfoliation process of the first two embodiments. Cleaning of the residual porous layer produces the structure at the bottom of the schematic cross-sectional view of FIG. 24 of an array of PV cells attached to the frontside glass 442 but with their P⁺ layer 422 exposed.

The cross-sectional view of FIG. 24 also illustrates the following backside fabrication steps corresponding to the beginning of step 514 of FIG. 22 on all the PV cells bonded to the frontside glass layer 442: (1) deposition and formation of the patterned passivation layers 450, (2) deposition of the titanium layers 452 on the passivation layers 450, and (3) deposition of the aluminum layers 454 on top of the titanium layers 454 and down into the contact openings 456 in the passivation layers 450 to make contact with the P⁺-type layers 422. Note that to avoid damaging the adhesion layer 332, all these steps and subsequent processing steps must be conducted at temperatures below the melting point of the adhesion material, such as EVA.

As was illustrated in FIG. 20 for the second embodiment, an alternative process to that illustrated in FIG. 24 is possible, which utilizes a laser beam to form contacts through otherwise unpatterned titanium and passivation layers. Since the differences between the second and third embodiments involve only the lower portions of the PV cells, not the surfaces above the P⁺ layers 422, the above description of this laser contact-forming process for the second embodiment in FIG. 20 is fully applicable for the third embodiment as well.

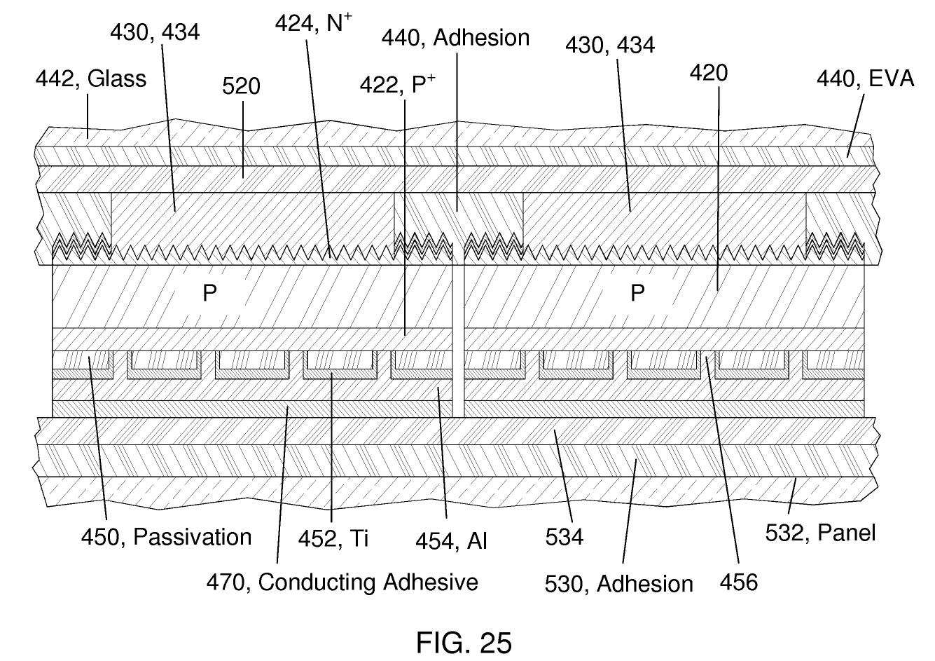

The schematic side cross-sectional view of FIG. 25, which has an inverted vertical orientation from that of FIG. 24, shows the solar cell array after simultaneously completing the following fabrication steps corresponding to steps 514 of FIG. 22 on all of the PV cells bonded to the frontside glass layer 442: (1) deposition of a conductive adhesive layer 470 on the backsides of the PV cells, (2) tabbing and stringing of the PV cells, and (3) attachment of a backside substrate using an adhesion layer.

The deposition method in step (1) for the conducting adhesive layer 470 depends on the type of conducting adhesive to be used: sheets, liquid or paste. These deposition methods are familiar to those skilled in the art. In steps (2) and (3), a backside adhesion layer 530, for example, a sheet of EVA is placed on a panel substrate 532, for example, of Tedlar (PVF). One or more long ribbons 534 are placed on the adhesion layer 530 to interconnect a string of PV cells in a parallel electrical connection. The array of PV cells attached to the frontside glass substrate 442 are then placed on the backside EVA adhesion layer 530 with the respective strings of PV cells aligned with different sets of the ribbons 534. The stack structure is then laminated, as described before, to both bond the stacked structure and to flow and harden the backside adhesion layer 530. Thereby, all the aluminum layers 545 in the string electrically contact the ribbon 534. More than one ribbon 534 may be used to string all the PV cells together along the length of each horizontal string, where each ribbon 534 makes contact to the conducting adhesive layer 470 adjacent every PV cell in the string. Note that steps (1) and (2) should be low temperature processes compatible with the frontside adhesion layer 332.

The electrical schematic diagram of FIG. 26 illustrates a solar panel 550 according to the third embodiment of the present invention. Each PV solar cell is represented as a diode 552, with several, N PV cells connected in parallel to form horizontal strings 554, each string 554 having an output current equal to the sum of the photovoltaically-generated currents of the N PV cells 552 of each string 554. In this example, M=8 strings 554, each containing six PV cells 2104, are connected in series by connections 556 near the sides of the finished solar panel 550. The connections may be made by interconnecting portions of the frontside and backside ribbons 520, 534 extending beyond the ends of their horizontal strings with anode of one horizontal string connected to the cathode of the neighboring string in the series connection. Thus, for the overall solar panel 550, the output current will be proportional to the number N of cells 552 in each string 554, and the output voltage will be equal to the output voltage of a single string 554 times the number M of strings 554 wired in series. External electrical connections 558, 560 may be made to different ones of the ribbons 520, 534 on the opposed ends of the series and output the solar power of the solar panel 550 to the electrical power network. With the same arrangements of PV cells as shown in FIGS. 9 and 26, the output currents and voltages for the second and third embodiments will be the same.

In the parallel connections of FIG. 26, the binning involves matching or nearly matching the open circuit voltages V_{OC} for each solar cell 552 in each of the strings 554. Matching of open circuit voltage between the strings 554 is not required.

The first embodiment can be readily adapted to the parallel connections of FIG. 24. Referring to FIG. 5, the parallel connections may be effected by aligning the P bus bars 314 of all the donor wafers 244 in the horizontal string with a single first long ribbon 334 and by aligning the N⁺ bus bars 316 on all these donor wafers 244 with a second long ribbon 334. The ribbons of opposite types are connected in series between the horizontal strings.

It will be understood by those skilled in the art that the foregoing descriptions are for illustrative purposes only. A number of modifications to the above manufacturing processes are possible within the scope of the present invention, such as the following.

The adhesion layers used to laminate the PV cells to the backside substrate or the frontside glass may be a material other than ethyl vinyl acetate (EVA).

The backside substrate may comprise Tedlar, a plastic material manufactured by DuPont. The backside substrate may comprise a material other than Tedlar, with the necessary structural characteristics to support the PV cell array in the solar panel. For example, the backside substrate may be glass. Alternatively, the backside substrate may be a polymerizing material, which is flowed onto the epitaxial sides of the donor wafers and then hardened to form a support layer.

The frontside glass layer may comprise, instead of glass, a clear plastic material or other transparent material.

The attachment of the ribbons to the PV cell contacts (bus bars) may be accomplished other than imbedding the ribbons in the adhesive.

Various methods for etching through the passivation layers are possible, such as wet etching, Reactive Ion Etching (RIE), or laser ablation. In the RIE process, the plasma would contain chemical species (ions and radicals) which react with the passivation layer. All these etching methods are well known to those skilled in the art and are not part of the present invention.

Other metals than aluminum and silver may be used for the interconnects and contacts.

The P-type and N-type doping may be interchanged.

The improved solar panel manufacturing process of the present invention affords improved yields through reduced breakage of PV cells during processing due to the mechanical support for the PV cells afforded by lamination to either the backside substrate or frontside glass layer. Materials costs are also substantially reduced through the use of donor wafers which may be recycled through multiple PV cell fabrication processes. The use of epitaxial deposition to form the PV cell layers leads to improved control over doping profiles and sharper junctions, leading to improved PV cell efficiency through reduced electron-hole recombination.

The invention allows robust handling of the PV cell formed in the epitaxial layer as it is transferred from the donor wafer to the mounting substrate since it is never left free-standing.

The invention allows the epitaxial layers to be formed at high temperatures and in sizes commonly found in the semiconductor industry while the remaining processing may be performed at lower temperatures and on large size panels promoting high throughput.

What is claimed is:

1. A solar panel manufacturing method, comprising a process for forming a multiplicity of photovoltaic (PV) cells, the process comprising the steps of:
forming separation layers on a multiplicity of donor wafers;
depositing on each of the separation layers a plurality of silicon layers including an n-type silicon layer, a p-type silicon layer, and contacts to at least some of the n-type and p-type silicon layers to form a multiplicity partially completed PV cells in the donor wafers, and
a combining step including tabbing at least some of the contacts on the multiplicity of partially completed PV cells and assembling the partially completed PV cells to form a string and bonding the string to a common first substrate using a first adhesion layer such that the silicon layers are disposed between the donor wafers and the first substrate.

2. The method as in claim 1, further including separating across the separation layers the donor wafers from the silicon layers and contacts bonded to the first substrate.

3. The method as in claim 2, wherein the separating step comprises the steps of:
clamping the donor wafers on sides opposite the n-type and p-type silicon layers with a wafer clamping assembly; and
applying a separating force between said wafer clamping assembly and the common substrate, the separating force inducing separation of the donor wafers from the n-type and p-type silicon layers at said separation layers.

4. The method as in claim 2, further comprising the step of:
a completing step of forming remaining portions of the PV cells on those of the n-type and p-type silicon layers uncovered by the separating step, thereby completing the PV cells.

5. The method as in claim 1, wherein each of the partially developed PV cells includes passivation and antireflection coatings on a textured surface to form a front side of the PV cell.

6. The method as in claim 5, wherein the common first substrate is a transparent substrate and the first adhesion layer at the completion of processing is transparent.

7. The method as in claim 6, wherein the first adhesion layer comprises ethyl vinyl acetate.

8. The method as in claim 4, wherein the completing step includes second depositing steps of depositing a second passivation layer over back sides of the partially completed PV cells and depositing a metal layer over the second passivation layer and forming contacts of the metal layer to the silicon layers through the second passivation layer.

9. The method as in claim 4, wherein the completing step includes a second depositing step of depositing passivation layers and anti-reflective coatings on front sides of the partially completed PV cells.

10. The method as in claim 9, wherein the completing step further comprises the step of bonding a transparent second substrate to the front sides of the PV cells using a second adhesion layer.

11. The method as in claim 10, wherein the second adhesion layer comprises ethyl vinyl acetate.

12. The method as in claim 9, wherein the string includes conductive lines connecting at least some of the contacts on different ones of the partially completed PV cells.

13. The method as in claim 1, wherein multiple strings are bonded side by side in parallel on the first substrate.

14. A solar panel manufacturing method, comprising a process for forming a multiplicity of PV cells, the process comprising the steps of:
forming separation layers on a multiplicity of donor wafers;
depositing first silicon layers of a first conductivity type on the separation layers on said donor wafers;
depositing second silicon layers of an opposite second conductivity type on the first silicon layers;
texturing the front surfaces of the second silicon layers;
forming passivating and anti-reflective layers on the textured front surfaces of the second silicon layers;
forming frontside contacts through the passivating and anti-reflective layers to the second silicon layers; and
a combining step including tabbing the frontside contacts and bonding the multiplicity of donor wafers to a transparent frontside mounting substrate using a first adhesion layer with the silicon layers disposed between the donor wafers and the mounting substrate.

15. The method as in claim 14, wherein the first adhesion layer comprises ethyl vinyl acetate.

16. The method as in claim 14, further comprising separating the donor wafers from the first and second silicon layers across the separation layer.

17. The method as in claim 14, wherein the separation layers comprise porous anodically etched silicon layers.

18. The method as in claim 14, further comprising the subsequent steps of:
depositing second passivation layers on the second silicon layers, each of the second passivation layers comprising a multiplicity of contact holes therethrough; and
depositing conductive layers on the passivation layers, the conductive layers making electrical contact with upper surfaces of the second silicon layers within the contact holes.

19. The method as in claim 14, wherein the steps of depositing the second passivation layers and the conductive layers are performed while maintaining a temperature of the mother wafers at less than 225 C.

20. The method as in claim 14, further comprising the subsequent steps of:
depositing conducting adhesive layers on said conductive layers; and
a second combining step including stringing together the multiplicity of PV cells by attachment of the frontside tabs to the conducting adhesive layers and bonding a backside substrate to the PV cells using a second adhesion layer.

21. The method as in claim 20, wherein the backside substrate comprises poly vinyl fluoride.

22. The method as in claim 14, further comprising the steps of:
depositing second passivation layers on the second silicon layers;
depositing conductive layers on the second passivation layers; and
focusing a laser beam on selected locations of the upper surfaces of the conductive layers, thereby inducing melting and penetration of the conductive layers through the passivation layers to form electrical contact from the conductive layers to the second silicon layers.

23. A solar panel manufacturing method, comprising a process for forming a multiplicity of PV cells, said process comprising the steps of:
forming separation layers on a multiplicity of donor wafers;
depositing first silicon layers of a first conductivity type on the separation layers on the donor wafers,
depositing second silicon layers of an opposite conductivity type on the second silicon layers to form the multiplicity of PV cells connected to respective ones of the donor wafers;
forming first contacts to the first silicon layers through the second siliocon layers;
forming second contacts to the second silicon layers;
stringing together a plurality of the PV cells with interconnections between first contacts of one PV cell and second contacts of an adjacent PV cell; and
bonding the multiplicity of donor wafers to a backside mounting substrate using a first adhesion layer, wherein the PV cells are disposed between the donor cells and the mounting substrate.

24. The method as in claim 23, further comprising the step of separating the donor wafers from the first and second silicon layers across the separation layers.

25. The method as in claim 24, further comprising the subsequent steps of:
texturing exposed surfaces of the first silicon layer;
depositing passivating and anti-reflective layers on the textured exposed surfaces.

26. The method as in claim 25, further comprising the steps of:
depositing an adhesion layer over the passivating and anti-reflective layers; and
then laminating a transparent frontside substrate to the passivating and anti-reflective layers, wherein the adhesion layer is transparent after the laminating step.

27. The method as in claim 23, wherein said separation layers are porous anodically etched silicon layers formed in the donor wafers.

28. The method as in claim 23, wherein the first substrate comprises poly vinyl fluoride.

29. A solar panel circuit comprising:
a multiplicity of strings, each string comprising a plurality of photovoltaic (PV) cells wired in parallel, each string having an input connection and an output connection;
wherein all of said input connections are wired together and wherein all of said output connections are wired together.
